(19) United States
(12) Patent Application Publication
(10) Pub. No.: US 2024/0274685 A1
(43) Pub. Date: Aug. 15, 2024

(54) SEMICONDUCTOR DEVICE AND METHOD OF MANUFACTURING THE SAME

(71) Applicant: Samsung Electronics Co., Ltd., Suwon-si (KR)

(72) Inventors: HEUNG-SOON LEE, Suwon-si (KR); YONGHEE PARK, Suwon-si (KR); DONG-GWAN SHIN, Suwon-si (KR); SEOKHOON KIM, Suwon-si (KR); SEUNGKYU KIM, Suwon-si (KR); HONGSEON YANG, Suwon-si (KR)

(21) Appl. No.: 18/242,399

(22) Filed: Sep. 5, 2023

(30) Foreign Application Priority Data
Feb. 9, 2023 (KR) 10-2023-0017329

(51) Int. Cl. H01L 29/423; H01L 29/06; H01L 29/08; H01L 29/417; H01L 29/775; H01L 29/786

(52) U.S. Cl. CPC H01L 29/42392; H01L 29/0673; H01L 29/0847; H01L 29/41775; H01L 29/775; H01L 29/78696

(57) ABSTRACT

A semiconductor device and a method of manufacturing the same are provided. A semiconductor device includes: an active pattern including a lower pattern and a plurality of sheet patterns spaced apart from each other on the lower pattern; a gate structure positioned on the lower pattern and surrounding the sheet patterns; source/drain patterns positioned on both sides of the gate structure, and stacked patterns positioned between the source/drain patterns and the sheet patterns, wherein a stacked pattern includes a first stacked pattern and a second stacked pattern sequentially stacked on a side surface of a sheet pattern, the second stacked pattern including a material different from a material of the first stacked pattern, and a first width of the sheet pattern is smaller than a second width of the gate structure.

### CROSS-REFERENCE TO RELATED APPLICATION

This application claims priority under 35 U.S.C. § 119 to and the benefit of Korean Patent Application No. 10-2023-0017329 filed in the Korean Intellectual Property Office on Feb. 9, 2023, the entire contents of which are incorporated herein by reference.

### 1. BACKGROUND

### Field

The present disclosure relates to a semiconductor device and a method of manufacturing the same.

### 2. DESCRIPTION OF THE RELATED ART

A semiconductor is a material belonging to an intermediate region between a conductor and a nonconductor, and refers to a material that conducts electricity under certain conditions. Various semiconductor devices can be manufactured by using these semiconductor materials, and for example, memory devices and the like can be manufactured. Such semiconductor devices may be used in various electronic devices.

As the electronics industry develops to a high degree, demands on the properties of semiconductor devices are gradually increasing. For example, demands for high reliability, high speed, and/or multifunctionality of semiconductor devices are gradually increasing. In order to satisfy these required characteristics, structures within semiconductor devices are becoming increasingly complex and integrated. As the size of the multi-gate transistor decreases, current controllability decreases and a short channel effect in which a potential of a channel region is affected by a drain voltage may occur.

### SUMMARY

Aspects of the present invention provide a semiconductor device with improved reliability and a method of manufacturing the same.

An embodiment provides a semiconductor device including: an active pattern including a lower pattern and a plurality of sheet patterns spaced apart from each other on the lower pattern; a gate structure positioned on the lower pattern and surrounding the sheet patterns; source/drain patterns positioned on both sides of the gate structure, and stacked patterns positioned between the source/drain patterns and the sheet patterns, wherein a stacked pattern includes a first stacked pattern and s second stacked pattern sequentially stacked on a side surface of a sheet pattern, the second stacked pattern including a material different from a material of the first stacked pattern, and a first width of the sheet pattern is smaller than a second width of the gate structure.

The gate structure may include: a main gate structure positioned on the sheet patterns, and a plurality of sub-gate structures positioned between the sheet patterns and between the sheet pattern and the lower pattern, wherein each of the plurality of sub-gate structures may include: a sub-gate electrode; and a gate insulating layer positioned between the sub-gate electrode and the sheet pattern and between the sub-gate electrode and the source/drain patterns, and wherein a third width of the sub-gate electrode may be greater than the first width.

The sub-gate structure may protrude toward a source/drain pattern more than the sheet pattern.

A side surface of the sub-gate structure facing the source/drain pattern may have a convex shape.

A side surface of the stacked pattern facing the source/drain pattern may have a concave shape.

The stacked pattern may be positioned between adjacent sub-gate structures.

A minimum width of the sheet pattern may be smaller than a maximum width of the sub-gate structure.

The semiconductor device may further include an inner spacer positioned between the sub-gate structure and the source/drain pattern, and the stacked pattern is positioned between inner spacers.

Concentrations of dopants in the first stacked pattern and the second stacked pattern may be different.

The dopants may be arsenic, boron, phosphorus, antimonium, or a combination thereof.

The concentrations of the dopants in the first stacked pattern and the second stacked pattern may be 1×10¹⁷ cm⁻³ to 1×10²² cm⁻³.

One of the first stacked pattern and the second stacked pattern may include silicon, and the other of the first stacked pattern and the second stacked pattern includes silicon germanium.

The stacked pattern may further include a third stacked pattern positioned between the second stacked pattern and the source/drain pattern, and the third stacked pattern and the second stacked pattern may include different materials from each other.

The third stacked pattern may include silicon or silicon germanium, and the second stacked pattern may include silicon carbide.

Another embodiment provides a semiconductor device including: an active pattern including a lower pattern and a plurality of sheet patterns spaced apart from each other on the lower pattern; sub-gate structures positioned on the lower pattern and surrounding the sheet patterns; source/drain patterns positioned on both sides of a sub-gate structure; and a stacked pattern positioned between a source/drain pattern and a sheet pattern, and including a first stacked pattern and a second stacked pattern sequentially stacked from a side surface of the sheet pattern, wherein at least one of materials of the first stacked pattern and the second stacked pattern, composition ratios of materials of the first stacked pattern and the second stacked pattern, and concentrations of dopants in the first stacked pattern and the second stacked pattern is different from each other between the first stacked pattern and the second stacked pattern.

The stacked pattern may further include a third stacked pattern positioned between the second stacked pattern and the source/drain pattern, and the third stacked pattern and the second stacked pattern may include different materials from each other.

The third stacked pattern may include silicon or silicon germanium, and the second stacked pattern may include silicon carbide.

The dopants are arsenic, boron, phosphorus, antimonium, or a combination thereof.

Still another embodiment provides a semiconductor device including: an active pattern including a lower pattern and a plurality of sheet patterns spaced apart from each other on the lower pattern; sub-gate structures positioned on the lower pattern and surrounding the sheet patterns; source/drain patterns positioned on both sides of a sub-gate structure, and stacked patterns positioned between the source/drain pattern and the sheet patterns, wherein the stacked patterns include a first stacked pattern and s second stacked pattern sequentially stacked on a side surface of a sheet pattern, the second stacked pattern including a material different from a material of the first stacked pattern, and the sub-gate structure protrudes toward a source/drain pattern more than the sheet pattern, and a side surface of the sub-gate structure is convex.

The sub-gate structure may protrude toward the source/drain pattern more than the stacked patterns.

According to the embodiments, characteristics of a semiconductor device may be improved by reducing leakage current (DIBL) of the semiconductor device and improving a short channel effect.

### BRIEF DESCRIPTION OF THE DRAWINGS

FIG. 1 is a top plan view illustrating a semiconductor device according to an embodiment.

FIG. 2 is a cross-sectional view taken along line A-A′ in FIG. 1.

FIG. 3 is a cross-sectional view taken along B-B′ of FIG. 1;

FIG. 4 is an enlarged view illustrating a region P1 of FIG. 2.

FIG. 5 is a graph illustrating alternating current performance ACS according to a displacement/offset distance of the semiconductor device according to some embodiments.

FIG. 6 is a graph illustrating direct current performance DCS according to a displacement/offset distance of the semiconductor device according to some embodiments.

FIG. 7 is a graph illustrating leakage current DIBL according to a displacement/offset distance of the semiconductor device according to some embodiments.

FIG. 8 is a graph illustrating resistivity of a sheet pattern according to a displacement/offset distance of the semiconductor device according to some embodiments.

FIG. 9 to FIG. 12 are enlarged views corresponding to the region P1 of FIG. 2 illustrating the semiconductor device according to some embodiments.

FIG. 13 is a cross-sectional view taken along line A-A′ of FIG. 1 and illustrating a semiconductor device according to an embodiment.

FIG. 14 is an enlarged view of a region P2 of FIG. 13.

FIG. 15 is an enlarged view corresponding to the region P2 of FIG. 13 illustrating the semiconductor device according to an embodiment.

FIGS. 16 to 18 and 20 to 22 are cross-sectional views illustrating intermediate steps of a method of manufacturing a semiconductor device according to an embodiment.

FIG. 19 is an enlarged view of a region S1 of FIG. 18.

FIGS. 23 to 25 are cross-sectional views illustrating a method of manufacturing a semiconductor device according to an embodiment.

FIG. 26 is an enlarged view of a region S2 of FIG. 25.

### DETAILED DESCRIPTION

In the following detailed description, only certain embodiments have been illustrated and described, simply by way of illustration. The present invention can be variously implemented and is not limited to the following embodiments.

The drawings and descriptions are to be regarded as illustrative in nature and not restrictive. Like reference numerals designate like elements throughout the specification.

In addition, the size and thickness of each configuration illustrated in the drawings are arbitrarily illustrated for understanding and ease of description, and the present invention is not limited thereto. In the drawings, the thicknesses of layers, films, panels, regions, etc., are exaggerated for clarity. In the drawings, for understanding and ease of description, the thicknesses of some layers and areas are exaggerated.

Further, it will be understood that when an element such as a layer, film, region, or substrate is referred to as being “on” another element, it can be directly on the other element or intervening elements may also be present. In contrast, when an element is referred to as being “directly on,” “in contact with,” or “contacting” another element, there are no intervening elements present. Other words used to describe the relationship between elements should be interpreted in a like fashion (e.g., “between” versus “directly between,” “adjacent” versus “directly adjacent,” etc.). In addition, being “above” or “on” a reference part means being located above or below the reference part, and does not necessarily mean being located “above” or “on” in the opposite direction of gravity. For example, spatially relative terms, such as “beneath,” “below,” “lower,” “above,” “upper” and the like, may be used herein for ease of description to describe positional relationships. It will be understood that the spatially relative terms encompass different orientations of the device in addition to the orientation depicted in the figures.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “in a plan view”, it means when a target part is viewed from above, and when it is referred to as “in a cross-section”, it means when the cross-section obtained by cutting a target part vertically is viewed from the side.

In a drawing of a semiconductor device according to an embodiment, Illustratively, a transistor including nanowires or nanosheets, a Multi-Bridge Channel Field Effect Transistor (MBCFETTM), and/or a fin-type transistor (FinFET) including a fin-type pattern-shaped channel region may be illustrated, but the present invention is not limited thereto. Of course, a semiconductor device according to some embodiments may include a tunneling transistor (tunneling FET) or a three-dimensional (3D) transistor.

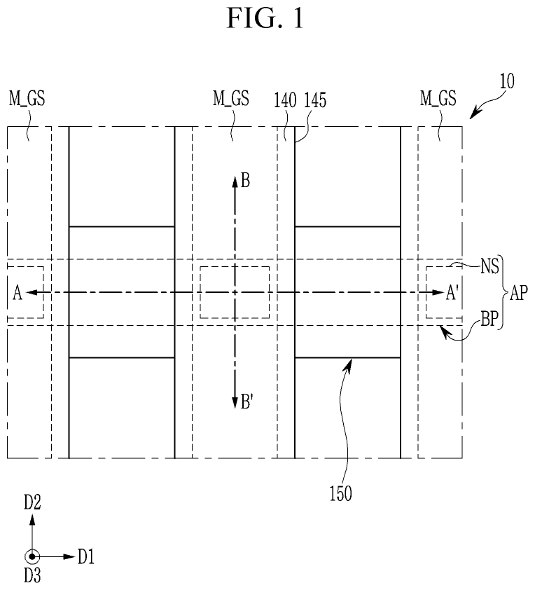

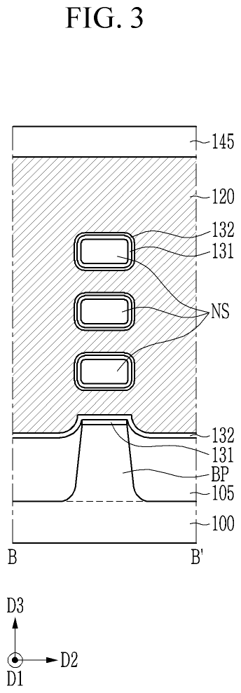

Referring to FIGS. 1 to 8, a semiconductor device according to an embodiment includes a substrate 100, an active pattern AP, a plurality of gate structures GS, a source/drain pattern 150, and a stacked pattern 200. A semiconductor device according to the embodiment may further include a gate spacer 140, a capping layer 145, 20) an etch stop layer 185, and an interlayer insulating layer 190.

The substrate 100 may be bulk silicon or silicon-on-insulator (SOI). Alternatively, the substrate 100 may also be a silicon substrate, or may be formed of another material or other materials, such as silicon germanium (SiGe), silicon germanium on insulator (SGOI), indium antimonide, lead tellurium compound, indium arsenic, indium phosphide, gallium arsenide, and/or gallium antimonide, but is not limited thereto. The upper surface of the substrate 100 may be disposed on a plane parallel to a first direction D1 and a second direction D2 crossing the first direction D1.

The active pattern AP may be positioned on the substrate 100. The active pattern AP may be elongated in the first direction D1. For example, the active pattern AP may be positioned in a region where a PMOS is formed. As another example, the active pattern AP may be positioned in a region where an NMOS is formed.

The active pattern AP may be a multi-channel active pattern. The active pattern AP may include a lower pattern BP and a plurality of sheet patterns NS. The lower pattern BP may protrude from the substrate 100. The lower pattern BP may be elongated in the first direction D1.

A plurality of sheet patterns NS may be positioned on an upper surface of the lower pattern. The plurality of sheet patterns NS may be spaced apart from the lower pattern BP in a third direction D3. The respective sheet patterns NS may be spaced apart in the third direction D3. Here, the third direction D3 may be a direction crossing the first direction D1 and the second direction D2. For example, the third direction D3 may be a thickness direction of the substrate 100. The second direction D2 may be a direction crossing the first direction D1.

Each sheet pattern NS may include an upper surface and a lower surface. The upper surface of the sheet pattern NS is opposite to the lower surface of the sheet pattern NS in the third direction D3. Each sheet pattern NS may further include a side surface NS_CS facing in the first direction D1. The side surface NS_CS of the sheet pattern may contact the stacked pattern 200 to be described later. The side surface NS_CS of the sheet pattern may be an interface between the sheet pattern NS and the stacked pattern 200.

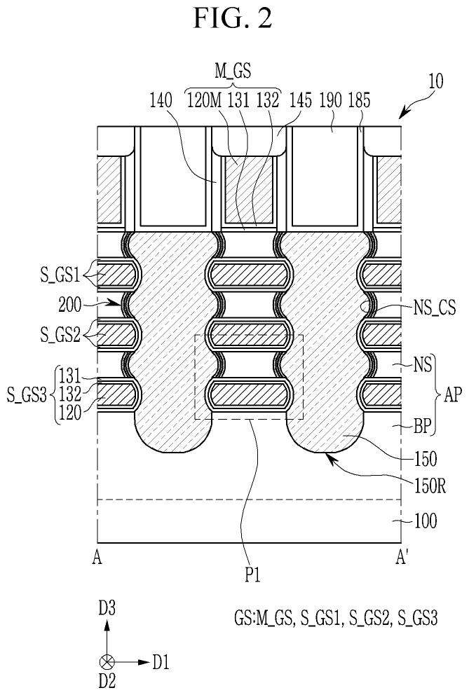

Although FIG. 2 illustrates that three sheet patterns NS are formed and spaced apart from each other and stacked along the third direction D3, this is only for convenience of explanation, and the present invention is not limited thereto. For example, four or more sheet patterns NS may be formed in the active pattern AP and spaced apart from each other along the third direction D3 and stacked in the third direction D3.

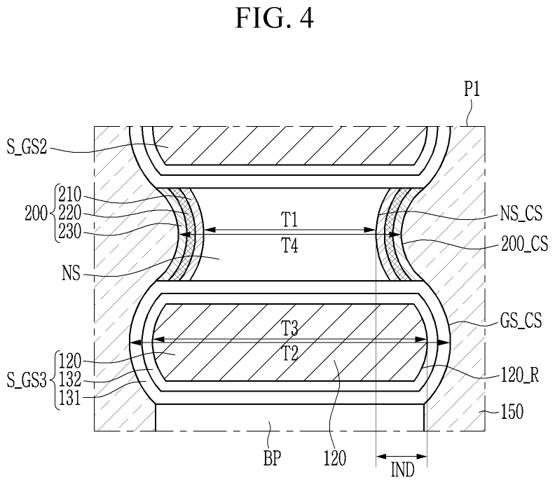

In FIGS. 2 and 4, the side surface NS_CS of the sheet pattern NS is illustrated to be a curved surface, but is not limited thereto. For example, the side surface NS_CS of the sheet pattern NS may be a combination of a curved surface and a flat/vertical (e.g., a vertical plane) surface, or may be entirely flat (e.g., on a vertical plane).

The lower pattern BP may also be formed by etching a portion of the substrate 100 or may include an epitaxial layer grown from the substrate 100. The lower pattern BP may include one or more kinds of elemental semiconductor materials, such as silicon (Si) or germanium (Ge). Also, the lower pattern BP may include a compound semiconductor, for example, a group IV-IV compound semiconductor or a group III-V compound semiconductor.

The group IV-IV compound semiconductor is, for example, a binary compound or a ternary compound including at least two or more of carbon (C), silicon (Si), germanium (Ge), and tin (Sn)).

The group III-V compound semiconductor may be, for example, one of a binary compound, a ternary compound, and a quaternary compound formed by combining at least one of aluminum (Al), gallium (Ga) and indium (In) as group Ill elements and one of phosphorus (P), arsenic (As), and antimonium (Sb) as group V elements.

The sheet pattern NS may include one of element semiconductor materials, such as silicon (Si) or silicon germanium (SiGe), a group IV-IV compound semiconductor, and a group III-V compound semiconductor. Each sheet pattern NS may also include or be formed of the same material(s) as that(those) of the lower pattern BP, or may include a material different from that of the lower pattern BP.

In the semiconductor device according to the embodiment, the lower pattern BP may be a silicon lower pattern including silicon (Si), and the sheet pattern NS may be a silicon sheet pattern including silicon (Si).

A field insulating layer 105 may be disposed on the substrate 100. The field insulating layer 105 may be positioned on (e.g., contact) the sidewall of the lower pattern BP. The field insulating layer 105 is not positioned on the upper/top surface of the lower pattern BP. For example, the field insulating layer 105 may not overlap the upper/top surface of the lower pattern BP in a vertical direction.

For example, the field insulating layer 105 may entirely cover the side surface of the lower pattern BP. For example, the field insulating layer 105 may overlap the whole of side surfaces of the lower pattern BP in a horizontal direction. Unlike illustration, the field insulating layer 105 may cover a portion of the sidewall of the lower pattern BP. For example, a portion of the side surfaces (sidewalls) of the lower pattern BP may not overlap the field insulating layer 105 in a horizontal direction, e.g., in the second direction D2. In this case, a portion of the lower pattern BP may protrude from the upper surface of the field insulating layer 105 in the third direction D3.

Each sheet pattern NS may be positioned higher than the upper surface of the field insulating layer 105. For example, each sheet pattern NS does not overlap the field insulating layer 105 in a horizontal direction. The field insulating layer 105 may include, for example, an oxide, a nitride, a nitroxide, or a combination layer thereof. Although the field insulating layer 105 is illustrated as a single layer, it is only for convenience of illustration, and is not limited thereto.

A plurality of gate structures GS may be positioned on the substrate 100. Each gate structure GS may extend in the second direction D2. The plurality of gate structures GS may be spaced apart from each other in the first direction D1.

The gate structure GS may be positioned on the active pattern AP. The gate structure GS may cross the active pattern AP. The gate structure GS may cross the lower pattern BP. The gate structure GS may surround each sheet pattern NS.

The gate structure GS may include a plurality of sub-gate structures S_GS1, S_GS2, and S_GS3, and a main gate structure M_GS. The plurality of sub-gate structures S_GS1, S_GS2, and S_GS3 may be positioned between sheet patterns NS adjacent to each other in the third direction D3 and between the lower pattern BP and the sheet pattern (e.g., the lowermost sheet pattern) NS. The main gate structure M_GS may be positioned on the uppermost sheet pattern NS.

The active pattern AP may include a plurality of sheet patterns NS, and the gate structure GS may include a plurality of sub-gate structures S_GS1, S_GS2, and S_GS3. The number of the plurality of sub-gate structures S_GS1, S_GS2, and S_GS3 may be proportional to the number of sheet patterns NS included in the active pattern AP. For example, the number of sub-gate structures S_GS1, S_GS2, and S_GS3 may be the same as the number of sheet patterns NS.

The plurality of sub-gate structures S_GS1, S_GS2, and S_GS3 may include a first sub-gate structure S_GS1, a second sub-gate structure S_GS2, and a third sub-gate structure S_GS3. The third sub-gate structure S_GS3, the second sub-gate structure S_GS2, and the first sub-gate structure S_GS1 may be sequentially positioned on the lower pattern BP. In the following description, a case in which the number of the plurality of sub-gate structures S_GS1, S_GS2, and S_GS3 is three will be described. However, it is not limited thereto, and may include four or more sub-gate structures.

The plurality of sub-gate structures S_GS1, S_GS2, and S_GS3 may be positioned between the upper surface of the lower pattern BP and the lower surface of the lowermost sheet pattern NS, and between each pair of the upper surfaces of the sheet patterns NS and the lower surfaces of the sheet patterns NS facing each other in the third direction D3.

The plurality of sub-gate structures S_GS1, S_GS2, and S_GS3 may contact the source/drain pattern 150 to be described later. For example, the plurality of sub-gate structures S_GS1, S_GS2, and S_GS3 may contact the source/drain pattern 150.

The plurality of sub-gate structures S_GS1, S_GS2, and S_GS3 may protrude toward the source/drain pattern 150 more than the sheet pattern NS. For example, the plurality of sub-gate structures S_GS1, S_GS2, and S_GS3 may protrude toward the source/drain pattern 150 from the side surfaces of the sheet pattern NS. For example, a first width T1 of the sheet pattern NS may be smaller than a second width T2 of the third sub-gate structure S_GS3. For example, the minimum width of the sheet pattern NS in the first direction D1, e.g., at the center of the sheet pattern NS in a vertical direction, may be smaller than the maximum width of the third sub-gate structure S_GS3 in the first direction D1, e.g., at the center of the third sub-gate structure S_GS3 in the vertical direction. The maximum width of the sheet pattern NS in the first direction D1, e.g., at the uppermost end/level and/or the lowermost end/level of the sheet pattern NS in the vertical direction, may be smaller than the maximum width of the third sub-gate structure S_GS3 in the first direction D1, e.g., at the center of the third sub-gate structure S_GS3 in the vertical direction. Here, the first width T1 of the sheet pattern NS may be the width of the sheet pattern NS along the first direction D1, and the second width T2 of the third sub-gate structure S_GS3 may be the width of the third sub-gate structure S_GS3 along the first direction D1. In certain embodiments, the maximum width of the sheet pattern NS in the first direction D1, e.g., at the uppermost end and/or the lowermost end of the sheet pattern NS in the vertical direction, may be smaller than the minimum width of the third sub-gate structure S_GS3 in the first direction D1, e.g., at the uppermost end/level and/or the lowermost end/level of the third sub-gate structure S_GS3 in the vertical direction.

Each of side surfaces of the plurality of sub-gate structures S_GS1, S_GS2, and S_GS3 may have a convex shape having a central portion protruding toward the source/drain pattern 150. For example, as illustrated in FIG. 4, a side surface GS_CS of the third sub-gate structure S_GS3 may have a curved convex shape having a central portion protruding toward the source/drain pattern 150. For example, the second width T2 of the third sub-gate structure S_GS3 may increase in a direction receding vertically from the bottom surface of third sub-gate structure S_GS3 to the center of the third sub-gate structure S_GS3 and may decrease in the direction receding vertically from the center to the top surface of the third sub-gate structure S_GS3. For example, the second width T2 of the third sub-gate structure S_GS3 may increase and then decrease in a direction receding from the bottom surface to the top surface of third sub-gate structure S_GS3.

Each of the plurality of sub-gate structures S_GS1, S_GS2, and S_GS3 may include a sub-gate electrode 120, an interfacial insulating layer 131, and a gate insulating layer 132.

The sub-gate electrode 120 may be disposed on the lower pattern BP. The sub-gate electrode 120 may cross the lower pattern BP. The sub-gate electrodes 120 may surround the sheet pattern NS.

At least a portion of the sub-gate electrode 120 may be positioned on the stacked structure (e.g., vertically stacked portions) of the sub-gate electrode 120 and the sheet pattern NS. Another portion of the sub-gate electrode 120 may be disposed to cover both/opposite sides of the stacked structure (e.g., vertically stacked portions) of the sub-gate electrode 120 and the sheet pattern NS. In this case, four surfaces of the sheet pattern NS may be surrounded by the sub-gate electrode 120.

The sub-gate electrodes 120 may be positioned on both sides of the source/drain pattern 150 to be described later. The gate structures GS may be positioned on both sides of the source/drain pattern 150 in the first direction D1.

The sub-gate electrodes 120 may protrude toward the source/drain pattern 150 more than the sheet pattern NS. For example, the sub-gate electrodes 120 may protrude toward the source/drain pattern 150 from side surfaces of the sheet patterns NS. For example, the third width T3 of the sub-gate electrode 120 may be greater than the first width T1 of the sheet pattern NS. For example, the maximum width of the sub-gate electrode 120 in the first direction D1, e.g., at the center of the sub-gate electrode 120 in a vertical direction, may be greater than the minimum width of the sheet pattern NS in the first direction D1, e.g., at the center of the sheet pattern NS in a vertical direction. The maximum width of the sub-gate electrode 120 in the first direction D1, e.g., at the center of the sub-gate electrode 120 in a vertical direction, may be greater than the maximum width of the sheet pattern NS in the first direction D1, e.g., at the uppermost end/level and/or at the lowermost end/level of the sheet pattern NS in the vertical direction. Here, the third width T3 of the sub-gate electrode 120 may be the width of the sub-gate electrode 120 extending in the first direction D1. In certain embodiments, the maximum width of the sheet pattern NS in the first direction D1, e.g., at the uppermost end and/or the lowermost end of the sheet pattern NS in the vertical direction, may be smaller than the minimum width of the sub-gate electrode 120 in the first direction D1, e.g., at the uppermost end/level and/or the lowermost end/level of the sub-gate electrode 120 in the vertical direction.

A side surface 120_R of the sub-gate electrode 120 may have a convex shape having a central portion protruding toward the source/drain pattern 150. For example, as illustrated in FIG. 4, the side surface 120_R of the sub-gate electrode 120 may have a partial circular shape having a central portion protruding toward the source/drain pattern 150. For example, the third width T3 of the sub-gate electrode 120 may increase in a direction receding vertically from the bottom surface of the sub-gate electrode 120 to the center of the sub-gate electrode, and may decrease in the direction receding vertically from the center to the top surface of the sub-gate electrode 120. For example, the third width T3 of the sub-gate electrode 120 may increase and then decrease in a direction receding vertically from the bottom surface to the top surface of the sub-gate electrode 120.

The sub-gate electrode 120 may include or be formed of at least one of a metal, a metal alloy, a conductive metal nitride, a metal silicide, a doped semiconductor material, a conductive metal oxide, and a conductive metal nitride. The sub-gate electrode 120 may include or be formed of, for example, at least one of titanium nitride (TIN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium Nitride (NbN), niobium Carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but is not limited thereto. The conductive metal oxide and the conductive metal nitroxide may include an oxidized form of the above material, but are not limited thereto.

The interfacial insulating layer 131 may extend along (e.g., contact) the upper surface of the lower pattern BP. The interfacial insulating layer 131 may be positioned along the circumference of the sheet pattern NS, e.g., in a cross-sectional view. The interfacial insulating layer 131 may contact the lower pattern BP, the source/drain pattern 150, and the sheet pattern NS. The interfacial insulating layer 131 may be interposed between the sheet pattern NS and the gate insulating layer 132.

The gate insulating layer 132 may extend along the upper surface of the field insulating layer 105 and the upper surface of the interfacial insulating layer 131. The gate insulating layer 132 may surround the plurality of sheet patterns NS. The gate insulating layer 132 may be positioned along the circumference of the sheet pattern NS, e.g., in a cross-sectional view. The gate insulating layer 132 may be interposed between the sub-gate electrode 120 and the interfacial insulating layer 131.

The interfacial insulating layer 131 may include or be formed of, for example, silicon oxide (SiO₂). The gate insulating layer 132 may include or be formed of, for example, a high-k (a high dielectric constant) material. The high dielectric constant material may include or may be a material having a higher dielectric constant than silicon oxide (SiO₂), such as hafnium oxide (HfO), aluminum oxide (AlO), or tantalum oxide (TaO).

The main gate structure M_GS may be positioned on the sub-gate structures S_GS1, S_GS2, and S_GS3 and the sheet patterns NS. The main gate structure M_GS may be positioned on (e.g., contact) the upper surface of the sheet pattern (e.g., the uppermost sheet pattern) NS.

The main gate structure M_GS may include a main gate electrode 120M, the interfacial insulating layer 131, and the gate insulating layer 132.

The main gate electrode 120M may be positioned on the sub-gate structures S_GS1, S_GS2, and S_GS3 and the sheet pattern NS. The main gate electrode 120M may be positioned on the upper surface of the sheet pattern (e.g., the uppermost sheet pattern) NS. The main gate electrode 120M may include or be formed of at least one of a metal, a metal alloy, a conductive metal nitride, a metal silicide, a doped semiconductor material, a conductive metal oxide, and a conductive metal nitroxide.

The interfacial insulating layer 131 of the main gate structure M_GS may extend along (e.g., contact) the upper surface of the sheet pattern NS. The interfacial insulating layer 131 of the main gate structure M_GS may not extend along (e.g., may not contact) a side surface of the gate spacer 140 to be described later. The interfacial insulating layer 131 of the main gate structure M_GS may include or be formed of, for example, silicon oxide (SiO₂). However, the interfacial insulating layer 131 of the main gate structure M_GS is not limited thereto, and may also extend along the side surface of the gate spacer 140 in certain embodiments.

The gate insulating layer 132 of the main gate structure M_GS may extend along (e.g., contact) the side surface and the lower surface of the main gate electrode 120M. The gate insulating layer 132 of the main gate structure M_GS may extend along (e.g., contact) the side surface of the gate spacer 140. The gate insulating layer 132 of the main gate structure M_GS may include or be formed of, for example, a high-k material.

The gate spacer 140 may be positioned on the side surface of the main gate electrode 120M. The gate spacer 140 is not disposed between the lower pattern BP and the sheet pattern (e.g., the lowermost sheet pattern) NS. The gate spacer 140 is not disposed between the sheet patterns NS adjacent in the third direction D3.

The gate spacer 140 may include or be formed of, for example, at least one of silicon nitride (SiN), silicon nitroxide (SiON), silicon oxide (SiO₂), silicon carbonate nitride (SiOCN), silicon boron nitride (SiBN), silicon oxyboronitride (SiOBN), silicon oxycarbide (SiOC) and combinations thereof. Although the gate spacer 140 is illustrated as being a single layer, it is only for convenience of description and is not limited thereto. For example, the gate spacer 140 may be formed of multiple layers of insulating material in certain embodiments.

The capping layer 145 may be positioned on the main gate structure M_GS and the gate spacer 140. An upper surface of the capping layer 145 and an upper surface of the interlayer insulating layer 190 may be on the same plane (e.g., coplanar). Unlike the illustration, the capping layer 145 may be positioned between the gate spacers 140 in certain embodiments.

The capping layer 145 may include or be formed of, for example, at least one of silicon nitride (SiN), silicon nitroxide (SiON), silicon (Si) carbonitride (SiCN), silicon carbonate nitride (SiOCN), and combinations thereof. The capping layer 145 may include or be formed of a material having an etch selectivity with respect to the interlayer insulating layer 190.

The source/drain pattern 150 may be positioned on (e.g., contact) the active pattern AP. For example, the source/drain pattern 150 may be positioned on (e.g., contact) the lower pattern BP.

The source/drain pattern 150 may be positioned in the source/drain recess 150R extending in the third direction D3. The source/drain pattern 150 may fill the source/drain recess 150R. A bottom surface of the source/drain recess 150R may be defined by the lower pattern BP. Side surfaces (e.g., sidewalls) of the source/drain recess 150R may be defined by the stacked pattern 200 and the plurality of sub-gate structures S_GS1, S_GS2, and S_GS3 to be described later.

The source/drain pattern 150 may be positioned on side surfaces of the sub-gate structures S_GS1, S_GS2, and S_GS3. For example, source/drain patterns 150 may contact side surfaces of the interfacial insulating layers 131 of the sub-gate structures S_GS1, S_GS2, and S_GS3. The source/drain pattern 150 may be positioned between sub-gate structures S_GS1, S_GS2, and S_GS3 adjacent in the first direction D1. For example, the source/drain patterns 150 may be positioned on both sides of the sub-gate structures S_GS1, S_GS2, and S_GS3.

The source/drain pattern 150 may be positioned on the side surface 200_CS of the stacked pattern 200 to be described later. For example, the source/drain pattern 150 may contact the side surface 200_CS of the stacked pattern 200. The source/drain pattern 150 may be positioned between stacked patterns 200 adjacent in the first direction D1.

The side surface of the source/drain pattern 150 may have a wavy shape including a concave portion and a convex portion. For example, side surfaces of the source/drain pattern 150 adjacent to (e.g., contacting) the sub-gate structures S_GS1, S_GS2, and S_GS3 may have a concave shape, and side surfaces of the source/drain pattern 150 adjacent to the sheet pattern NS may have a convex shape.

The source/drain patterns 150 may be epitaxial patterns formed by a selective epitaxial growth process using the active pattern AP as a seed. The source/drain pattern 150 may include or be formed of, for example, at least one of silicon (Si) and silicon germanium (SiGe). The sheet pattern NS may be a part of the active pattern AP extending between the source/drain patterns 150. The source/drain pattern 150 may serve as a source/drain of a transistor using the sheet pattern NS as a channel region.

The stacked pattern 200 may be positioned between the source/drain pattern 150 and the sheet pattern NS. The stacked pattern 200 may be positioned on both sides of the sheet pattern NS. The stacked pattern 200 may extend along the side surface NS_CS of the sheet pattern NS. The stacked pattern 200 may cover the side surface NS_CS of the sheet pattern NS. The stacked pattern 200 may be conformally formed along the profile of the sheet pattern NS. The stacked pattern 200 may contact the side surface NS_CS of the sheet pattern NS. The side surface 200_CS of the stacked pattern 200 may contact the source/drain pattern 150. For example, the stacked pattern 200 may have opposite side surfaces respectively contacting the source/drain pattern 150 and the sheet pattern NS, e.g., in a cross-sectional view.

The stacked pattern 200 may be positioned between the sub-gate structures S_GS1, S_GS2, and S_GS3 adjacent (e.g., directly adjacent) in the third direction D3. For example, the stacked patterns 200 may be positioned at least one of the space between the third sub-gate structure S_GS3 and the second sub-gate structure S_GS2, the space between the second sub-gate structure S_GS2 and the first sub-gate structure S_GS1, and the space between the first sub-gate structure S_GS1 and the main gate structure M_GS, adjacent (e.g., directly adjacent) to each other in the third direction D3, respectively. For example, the stacked patterns 200 may vertically overlap the first sub-gate structure S_GS1, the second sub-gate structure S_GS2 and the third sub-gate structure S_GS3. However, the stacked pattern 200 is not limited thereto and the stacked pattern 200 may be positioned at least one of the space between the third sub-gate structure S_GS3 and the second sub-gate structure S_GS2, the space between the second sub-gate structure S_GS2 and the first sub-gate structure S_GS1, and the space between the first sub-gate structure S_GS1 and the main gate structure M_GS, adjacent (e.g., directly adjacent) to each other in the third direction D3.

Also, the stacked patterns 200 adjacent (e.g., directly adjacent) in the third direction D3 may be separated from each other. The stacked patterns 200 may be spaced apart from each other along the second direction D2. The stacked pattern 200 may be disposed not to cover/contact side surfaces of the sub-gate structures S_GS1, S_GS2, and S_GS3. For example, the stacked pattern 200 positioned on the upper side of (e.g., above) the second sub-gate structure S_GS2 and the stacked pattern 200 positioned on the lower side of (e.g., below) the second sub-gate structure S_GS2 may be separated (e.g., spaced apart) from each other, e.g., in the vertical direction (the third direction D3).

The stacked pattern 200 may contact the sub-gate structures S_GS1, S_GS2, and S_GS3. For example, the stacked pattern 200 may contact the upper surface of the third sub-gate structure S_GS3 and the lower surface of the second sub-gate structure S_GS2. For example, the stacked patterns 200 may contact each of the upper surface of the second sub-gate structure S_GS2, the upper surface of the first sub-gate structure S_GS1, the lower surface of the first sub-gate structure S_GS1, and the lower surface of the main gate structure M_GS.

The stacked pattern 200 may have a concave shape, e.g., on a surface facing the source/drain pattern 150, and the surface facing the source/drain pattern 150 is positioned closer to a center of the sheet pattern NS than side surfaces of the sub-gate structures S_GS1, S_GS2, and S_GS3 in a horizontal direction (e.g., the first direction D1). For example, the stacked pattern 200 may have a shape concave, e.g., on the surface facing the source/drain pattern 150 and the surface facing the source/drain pattern 150 may be positioned in the first direction D1 closer to the center of the sheet pattern NS than a side surface of the third sub-gate structure S_GS3 facing the source/drain pattern 150.

The side surface 200_CS of the stacked pattern 200 facing the source/drain pattern 150 may have a concave shape. For example, the side surface 200_CS of the stacked pattern 200 forming a boundary with (e.g., contacting) the source/drain pattern 150 may have a concave shape, but is not limited thereto.

The space between the side surfaces 200_CS of the stacked patterns 200 positioned on both sides of the sheet pattern NS may have a fourth width T4 in the first direction D1. In this case, the side surface 200_CS of the stacked pattern 200 may mean an outer surface in contact with the source/drain pattern 150. Hereinafter, the fourth width T4 between the side surfaces 200_CS of the stacked pattern 200 is defined as the distance between the side surfaces 200_CS of the stacked pattern 200 positioned on both sides of one sheet pattern NS.

The fourth width T4 between the side surfaces 200_CS of the stacked pattern 200 may be smaller than the second width T2 of the sub-gate structures S_GS1, S_GS2, and S_GS3. For example, the sub-gate structures S_GS1, S_GS2, and S_GS3 may protrude toward the source/drain pattern 150 more than (e.g., from) the stacked pattern 200, and the maximum width (e.g., the maximum value of the fourth width T4) between the stacked pattern 200 positioned on both sides of the sheet pattern NS may be smaller than the second width T2 of the sub-gate structures S_GS1, S_GS2, and S_GS3.

As the distance from the upper surface of the third sub-gate structure S_GS3 increases (e.g., upwardly in a vertical direction), the stacked pattern 200 may include a portion in which the fourth width T4 between the side surfaces 200_CS of the stacked pattern 200 decreases, and a portion in which the fourth width T4 between the side surfaces 200_CS of the stacked pattern 200 increases. For example, as the distance from the upper surface of the third sub-gate structure S_GS3 increases (e.g., upwardly in the vertical direction), the fourth width T4 between the side surfaces 200_CS of the stacked pattern 200 may decrease and then increase, e.g., in a direction moving vertically. A point where the fourth width T4 between the side surfaces 200_CS of the stacked pattern 200 is maximum may be positioned between the sheet patterns NS and the sub-gate structures S_GS1, S_GS2, and S_GS3, e.g., at a boundary between the sheet patterns NS and the sub-gate structures S_GS1, S_GS2, and S_GS3. In addition, a point where the fourth width T4 between the side surfaces 200_CS of the stacked pattern 200 is minimum may be positioned within the sheet pattern NS, but is not limited thereto. For example, the fourth width T4 may have a minimum value at a central level of the stacked pattern 200.

The stacked pattern 200 may include a first stacked pattern 210, a second stacked pattern 220, and a third stacked pattern 230 sequentially stacked (e.g., in a horizontal direction—the first direction D1) from the side surface NS_CS of the sheet pattern NS. The first stacked pattern 210, the second stacked pattern 220, and the third stacked pattern 230 may be sequentially stacked from the side surface NS_CS of the sheet pattern NS (e.g., in the horizontal direction) between the source/drain pattern 150 and the sheet pattern NS.

The first stacked pattern 210 may be positioned on the sheet pattern NS. The first stacked pattern 210 may extend along the side surface NS_CS of the sheet pattern NS. The first stacked pattern 210 may cover/contact the side surface NS_CS of the sheet pattern NS. The first stacked pattern 210 may be conformally formed along the profile of the side surface NS_CS of the sheet pattern NS.

The first stacked pattern 210 may have a concave shape, e.g., at a side surface facing the second stacked pattern 220. For example, the first stacked pattern 210 may have a concave shape, e.g., on a side surface facing the second stacked pattern 220 in the first direction D1 recessing toward the sheet pattern NS and the side surface facing the second stacked pattern 220 may be positioned closer to a center of the sheet pattern NS than a side surface of the third sub-gate structure S_GS3 facing the source/drain pattern 150. For example, the side surface of the first stacked pattern 210 may have a concave shape.

The second stacked pattern 220 may be positioned on the first stacked pattern 210. The second stacked pattern 220 may extend along the side surface of the first stacked pattern 210. The second stacked pattern 220 may cover/contact the side surface of the first stacked pattern 210. The second stacked pattern 220 may be conformally formed along the profile of the side surface of the first stacked pattern 210.

The second stacked pattern 220 may have a concave shape, e.g., on a side surface facing the third stacked pattern 230, e.g., recessing toward the sheet pattern NS. For example, the second stacked pattern 220 may have a concave shape, e.g., at the side surface facing the third stacked pattern 230, e.g., recessing in the first direction D1 toward the sheet pattern NS, and may be positioned closer to a center of the sheet pattern NS than a side surface of the third sub-gate structure S_GS3 facing the source/drain pattern 150. For example, the side surface of the second stacked pattern 220 may have a concave shape.

The third stacked pattern 230 may be positioned on the second stacked pattern 220. The third stacked pattern 230 may extend along the side surface of the second stacked pattern 220. The third stacked pattern 230 may cover/contact the side surface of the second stacked pattern 220. The third stacked pattern 230 may be conformally formed along the profile of the side surface of the second stacked pattern 220. The third stacked pattern 230 may be positioned on (e.g., contact) the source/drain pattern 150. For example, the third stacked pattern 230 may be positioned between the second stacked pattern 220 and the source/drain pattern 150.

The third stacked pattern 230 may have a concave shape, e.g., on a side surface facing the source/drain pattern 150, e.g., recessing toward the sheet pattern NS. For example, the third stacked pattern 230 may have a concave shape, e.g., at the side surface facing the source/drain pattern 150, e.g., recessing in the first direction D1 toward the sheet pattern NS and may be positioned closer to a center of the sheet pattern NS than a side surface of the third sub-gate structure S_GS3 facing the source/drain pattern 150. For example, the side surface of the third stacked pattern 230 forming a boundary with the source/drain pattern 150 may have a concave shape.

Although it is illustrated that three stacked patterns 200 of the semiconductor device according to the embodiment are disposed between the source/drain pattern 150 and the sheet pattern NS, the stacked pattern 200 is not limited thereto. For example, two or less stacked patterns 200 may be disposed between the source/drain pattern 150 and the sheet pattern NS, or four or more stacked patterns 200 may be disposed between the source/drain pattern 150 and the sheet pattern NS.

At least one of the first stacked pattern 210, the second stacked pattern 220, and the third stacked pattern 230 may include or be formed of different materials. For example, the third stacked pattern 230 may include or be formed of a material different from the first stacked pattern 210 or the second stacked pattern 220. The first stacked pattern 210 may include or be formed of a material different from that of the second stacked pattern 220.

For example, when the third stacked pattern 230 includes or is formed of a first material, the first stacked pattern 210 or the second stacked pattern 220 may include or be formed of a second material different from the first material. In this case, when any one of the first stacked pattern 210 and the second stacked pattern 220 includes or is formed of the second material, the other one of the first stacked pattern 210 and the second stacked pattern 220 may include or be formed of a third material different from the second material. However, materials are not limited thereto, and when the third stacked pattern 230 includes or is formed of a material different from that of the first stacked pattern 210 or the second stacked pattern 220, the first stacked pattern 210 and the second stacked pattern 220 may include the same material as each other.

Here, the first material may be, for example, silicon (Si), silicon germanium (SiGe), or a combination thereof. The second material may be, for example, silicon (Si), silicon germanium (SiGe), silicon carbide (SIC), or a combination thereof. The third material may be, for example, silicon (Si), silicon germanium (SiGe), or a combination thereof.

For example, the second stacked pattern 220 may include or be formed of silicon carbide (SiC), the third stacked pattern 230 may include or be formed of silicon (Si) or silicon germanium (SiGe), and the first stacked pattern 210 may include or be formed of silicon (Si) or silicon germanium (SiGe). Alternatively, the first stacked pattern 210 may include or be formed of silicon (Si), the second stacked pattern may include or be formed of silicon carbide (SIC), and the third stacked pattern 230 may include or be formed of silicon germanium (SiGe). Alternatively, the first stacked pattern 210 and the third stacked pattern 230 may include or be formed of silicon germanium (SiGe), and the second stacked pattern may include or be formed of silicon carbide (SIC). Alternatively, the first stacked pattern 210 and the third stacked pattern 230 may include or be formed of silicon (Si), and the second stacked pattern may include or be formed of silicon carbide (SiC), but materials are not limited thereto.

Referring back to FIG. 2, the etch stop layer 185 may be positioned on (e.g., contact) a side surface of the gate spacer 140 and an upper surface of the source/drain pattern 150. The etch stop layer 185 may include or be formed of a material having an etch selectivity with respect to the interlayer insulating layer 190 to be described later. The etch stop layer 185 may include or be formed of, for example, at least one of silicon nitride (SiN), silicon nitroxide (SiON), silicon carbonate nitride (SiOCN), silicon boron nitride (SiBN), silicon oxyboronitride (SiOBN), or silicon oxycarbide (SiOC), and combinations thereof.

The interlayer insulating layer 190 may be positioned on (e.g., contact) the etch stop layer 185. The interlayer insulating layer 190 may be positioned on (e.g., vertically overlap) the source/drain pattern 150. The interlayer insulating layer 190 may not cover (e.g., may not vertically overlap) the upper surface of the capping layer 145.

The interlayer insulating layer 190 may include or be formed of, for example, at least one of silicon oxide (SiO₂), silicon nitride (SiN), silicon nitroxide (SiON), and a low-k material. The low-k material may include or may be, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyClo TetraSiloxane (OMCTS), HexaMethylDiSiloxane (HMDS), TriMethylSilylBorate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped Silicon Oxide), OSG (Organo Silicate Glass), SILK, Amorphous Fluorinated Carbon, silica aerogels, silica xerogels, mesoporous silica, or a combination thereof, but is not limited thereto.

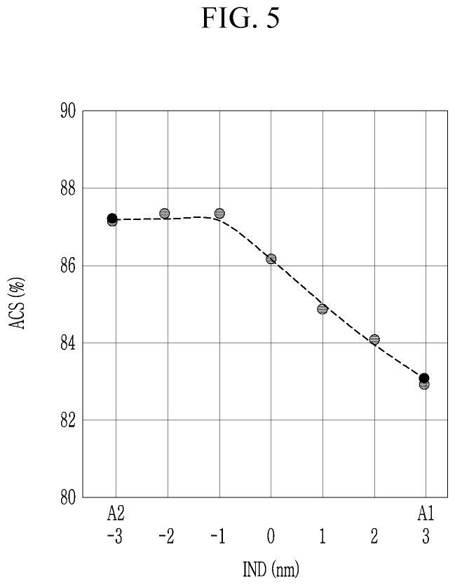

Hereinafter, characteristics of a semiconductor device according to an embodiment will be described with further reference to FIGS. 5 to 8.

FIG. 5 is a graph illustrating alternating current performance ACS of a semiconductor device according to an embodiment. FIG. 5 illustrates alternating current performance ACS according to a displacement/offset distance IND between the sub-gate structures S_GS1, S_GS2, and S_GS3 and the sheet pattern NS of the semiconductor device according to the embodiment.

First, differently from the one illustrated in FIG. 4, the sheet pattern NS may protrude toward the source/drain pattern 150 more than the sub-gate structures S_GS1, S_GS2, and S_GS3 by a displacement/offset distance IND. For example, like the semiconductor device according to the embodiment, when the sub-gate structures S_GS1, S_GS2, and S_GS3 protrude toward the source/drain pattern 150 more than the sheet pattern NS, the displacement/offset distance IND may have a negative value. Alternatively, when the sheet pattern NS protrudes toward the source/drain pattern 150 more than the sub-gate structures S_GS1, S_GS2, and S_GS3, the displacement/offset distance IND may have a positive value. Hereinafter, a gap/distance by which the sheet pattern NS protrudes toward the source/drain pattern 150 more than the sub-gate structures S_GS1, S_GS2, and S_GS3 by the displacement/offset distance IND is defined as the displacement/offset distance IND.

Referring to FIG. 5, the alternating current performance ACS is a value obtained by applying an AC current to a semiconductor device to evaluate an AC operation characteristic and converting the value into a percentile (%). Alternating current performance ACS may be, for example, a value obtained by evaluating dynamic characteristics, such as input/output switching time and operation time, of the semiconductor device according to the embodiment. Therefore, it may be considered that the characteristics of the semiconductor device are improved and the reliability is improved as the alternating current performance ACS of the semiconductor device is increased. For example, the value of the alternating current performance ACS of the semiconductor device may be high when response time is fast (e.g., when the input/output time is short and/or when the operation time is long), and the value of the alternating current performance ACS of the semiconductor device may be low when response time is slow (e.g., when the input/output time is long and/or when the operation time is long).

Alternating current performance ACS may increase as the displacement/offset distance IND decreases. For example, alternating current performance ACS may increase (e.g., may have a high value) as the sub-gate structures S_GS1, S_GS2, and S_GS3 protrude toward the source/drain pattern 150 more than the sheet pattern NS. Conversely, as the sheet pattern NS protrudes toward the source/drain pattern 150 more than the sub-gate structures S_GS1, S_GS2, and S_GS3, the alternating current performance ACS may decrease (e.g., may have a low value).

For example, when the displacement/offset distance IND is 3 nm, the alternating current performance ACS of a first point A1 may be 82% or more and 84% or less (e.g., between 82% and 84%). For example, when the sheet pattern NS protrudes 3 nm more than the sub-gate structures S_GS1, S_GS2, and S_GS3 toward the source/drain pattern 150, the alternating current performance ACS of the semiconductor device may be 82% or more and 84% or less. When the displacement/offset distance IND is −3 nm, the alternating current performance ACS of a second point A2 may be 86% or more and 88% or less (e.g., between 86% and 88%). For example, when the sub-gate structures S_GS1, S_GS2, and S_GS3 protrude 3 nm more than the sheet pattern NS toward the source/drain pattern 150, alternating current performance ACS of the semiconductor device may be 86% or more and 88% or less. For example, the alternating current performance ACS of the second point A2 may be greater than the alternating current performance ACS of the first point A1.

In the semiconductor device according to the embodiment, the sub-gate structures S_GS1, S_GS2, and S_GS3 protrude more than the sheet pattern NS toward the source/drain pattern 150, so that alternating current performance ACS of the semiconductor device may be increased/higher than the case where the sheet pattern NS protrudes more than the sub-gate structures S_GS1, S_GS2, and S_GS3 toward the source/drain pattern 150. Accordingly, the characteristics of the semiconductor device may be improved.

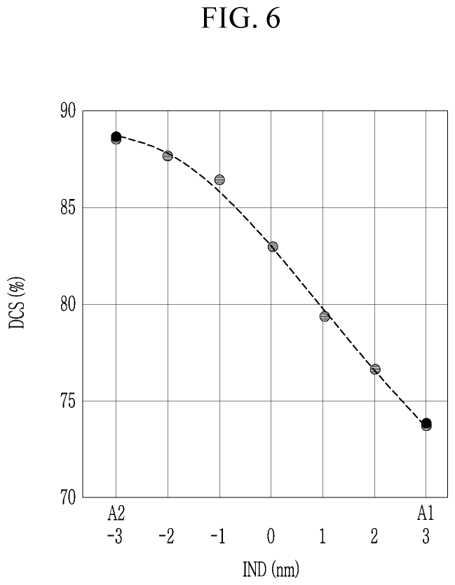

FIG. 6 is a graph illustrating direct current performance DCS of the semiconductor device according to some embodiments. FIG. 6 illustrates direct current performance DCS according to a displacement/offset distance IND between the sub-gate structures S_GS1, S_GS2, and S_GS3 and the sheet pattern NS of the semiconductor device according to the embodiments.

Referring to FIG. 6, the direct current performance DCS is a value obtained by applying a DC current to a semiconductor device to evaluate DC operation characteristics, and converting the value into a percentile (%). The direct current performance DCS may be, for example, a value obtained by evaluating whether the semiconductor device according to the embodiments is short-circuited or open, whether leakage current occurs between terminals of the semiconductor device according to an embodiment (for example, between the source/drain pattern 150 and the sub-gate structure or between the source/drain pattern 150 and the sheet pattern NS), or whether input/output voltages of the semiconductor device according to the embodiment are within an allowable range. Therefore, it may be considered that the characteristics of the semiconductor device are improved and the reliability is improved as the direct current performance DCS of the semiconductor device is increased. For example, the higher percentage value of the direct current performance DCS represents the better characteristics and reliability of the semiconductor device.

As the displacement/offset distance IND decreases, the direct current performance DCS may increase. For example, the direct current performance DCS may increase as the sub-gate structures S_GS1, S_GS2, and S_GS3 protrude more than the sheet pattern NS toward the source/drain pattern 150. For example, as the sheet pattern NS protrudes more than the sub-gate structures S_GS1, S_GS2, and S_GS3 toward the source/drain pattern 150, the direct current performance DCS may decrease.

For example, when the displacement/offset distance IND is 3 nm, the direct current performance DCS of the first point A1 may be 70% or more and 75% or less (e.g., between 70% and 75%). For example, when the sheet pattern NS protrudes 3 nm more than the sub-gate structures S_GS1, S_GS2, and S_GS3 toward the source/drain pattern 150, the direct current performance DCS of the semiconductor device may be 70% or more and 75% or less. When the displacement/offset distance IND is −3 nm, the direct current performance DCS of the second point A2 may be 85% or more and 90% or less (e.g., between 85% and 90%). For example, when the sub-gate structures S_GS1, S_GS2, and S_GS3 protrude 3 nm more than the sheet pattern NS toward the source/drain pattern 150, the direct current performance DCS of the semiconductor device may be 85% or more and 90% or less. The direct current performance DCS of the second point A2 may be greater than direct current performance DCS of the first point A1.

In the semiconductor device according to the embodiment, the sub-gate structures S_GS1, S_GS2, and S_GS3 protrude more than the sheet pattern NS toward the source/drain pattern 150, so that the direct current performance DCS of the semiconductor device may be increased/higher than the case where the sheet pattern NS protrudes more than the sub-gate structures S_GS1, S_GS2, and S_GS3 toward the source/drain pattern 150. Accordingly, the characteristics of the semiconductor device may be improved.

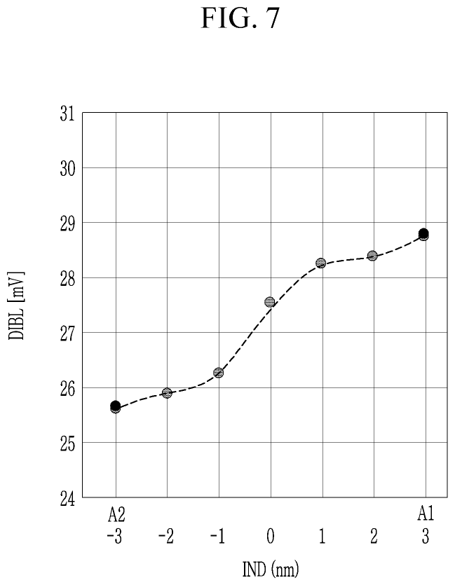

FIG. 7 is a graph illustrating leakage current DIBL of the semiconductor device according to some embodiments. FIG. 7 illustrates a leakage current DIBL according to the displacement/offset distance IND between the sub-gate structures S_GS1, S_GS2, and S_GS3 of the semiconductor device and the sheet pattern NS according to the embodiments.

Referring to FIG. 7, the leakage current DIBL may be a forward current flowing in a source of the semiconductor device according to the embodiments. The leakage current DIBL may occur due to a drain-induced barrier lowering phenomenon in which an energy barrier between the source/drain patterns 150 of the semiconductor device is lowered. The drain-induced barrier lowering phenomenon is an example of a short channel effect, and may cause a problem of reducing a threshold voltage of a semiconductor device. Therefore, it may be considered that the characteristics of the semiconductor device are improved and the reliability is improved as the leakage current DIBL of the semiconductor device is reduced.

As the displacement/offset distance IND decreases, the leakage current DIBL may decrease. For example, the leakage current DIBL may decrease as the sub-gate structures S_GS1, S_GS2, and S_GS3 protrude more than the sheet pattern NS toward the source/drain pattern 150. For example, as the sheet pattern NS protrudes more than the sub-gate structures S_GS1, S_GS2, and S_GS3 toward the source/drain pattern 150, the leakage current DIBL may increase.

For example, when the displacement/offset distance IND is 3 nm, the leakage current DIBL of the first point A1 may be 28 mV or more and 29 mV or less (e.g., between 28 mV and 29 mV). For example, when the sheet pattern NS protrudes 3 nm more than the sub-gate structures S_GS1, S_GS2, and S_GS3 toward the source/drain pattern 150, the leakage current DIBL of the semiconductor device may be 28 mV or more and 29 mV or less. When the displacement/offset distance IND is −3 nm, the leakage current DIBL of the second point A2 may be 25 mV or more and 26 mV or less (e.g., between 25 mV and 26 mV). For example, when the sub-gate structures S_GS1, S_GS2, and S_GS3 protrude 3 nm more than the sheet pattern NS toward the source/drain pattern 150, the leakage current DIBL of the semiconductor device may be 25 mV or more and 26 mV or less. For example, the leakage current DIBL of the second point A2 may be smaller than the leakage current DIBL of the first point A1.

In the semiconductor device according to the embodiments, the sub-gate structures S_GS1, S_GS2, and S_GS3 protrude more than the sheet pattern NS toward the source/drain pattern 150, so that the leakage current DIBL of the semiconductor device may be reduced/lower than the case where the sheet pattern NS protrudes more than the sub-gate structures S_GS1, S_GS2, and S_GS3 toward the source/drain pattern 150. Accordingly, the characteristics of the semiconductor device may be improved.

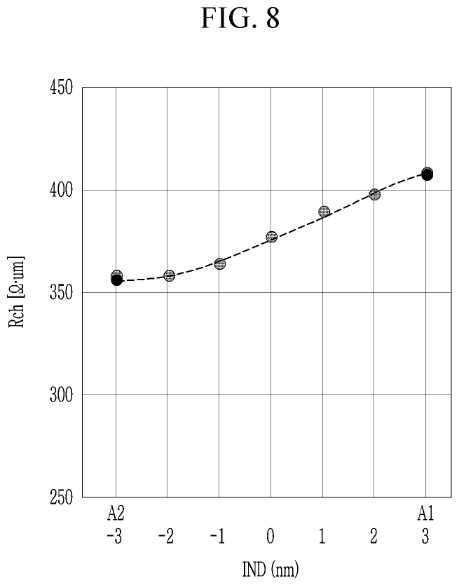

FIG. 8 is a graph illustrating resistivity of a sheet pattern of the semiconductor device according to some embodiments. FIG. 8 illustrates resistivity Rch of the sheet pattern according to the displacement/offset distance IND between the sub-gate structures S_GS1, S_GS2, and S_GS3 of the semiconductor device and the sheet pattern NS according to the embodiments.

Referring to FIG. 8, the resistivity Rch of the sheet pattern NS may be the resistivity of the sheet pattern NS of the semiconductor device according to the embodiments. It may be considered that as the resistivity Rch of the sheet pattern NS of the semiconductor device is reduced, the characteristics of the semiconductor device are improved and the reliability is improved.

As the displacement/offset distance IND decreases, the resistivity Rch of the sheet pattern NS may decrease. For example, as the sub-gate structures S_GS1, S_GS2, and S_GS3 protrude more than the sheet pattern NS toward the source/drain pattern 150, the resistivity Rch of the sheet pattern NS may decrease. For example, as the sheet pattern NS protrudes more than the sub-gate structures S_GS1, S_GS2, and S_GS3 toward the source/drain pattern 150, the resistivity Rch of the sheet pattern NS may increase.

For example, when the displacement/offset distance IND is 3 nm, the resistivity Rch of the sheet pattern NS at the first point A1 may be 400 Ωum or more and 450 Ωum or less (e.g., between 400 Ωum and 450 Ωum). For example, when the sheet pattern NS protrudes 3 nm more than the sub-gate structures S_GS1, S_GS2, and S_GS3 toward the source/drain pattern 150, the resistivity Rch of the sheet pattern NS may be 400 Ωum or more and 450 Ωum or less. When the displacement/offset distance IND is −3 nm, the resistivity Rch of the sheet pattern NS at the second point A2 may be 350 Ωum or more and 400 Ωum or less (e.g., between 350 Ωum and 400 Ωum). For example, when the sub-gate structures S_GS1, S_GS2, and S_GS3 protrude 3 nm more than the sheet pattern NS toward the source/drain pattern 150, the resistivity Rch of the sheet pattern NS may be 350 Ωum or more and 400 Ωum or less. For example, the resistivity Rch of the sheet pattern NS at the second point A2 may be smaller than the resistivity Rch of the sheet pattern NS at the first point A1.

In the semiconductor device according to the embodiments, the sub-gate structures S_GS1, S_GS2, and S_GS3 protrude more than the sheet pattern NS toward the source/drain pattern 150, so that the resistivity Rch of the sheet pattern NS of the semiconductor device may decrease or be lower than the case where the sheet pattern NS protrudes more than the sub-gate structures S_GS1, S_GS2, and S_GS3 toward the source/drain pattern 150. Accordingly, the characteristics of the semiconductor device may be improved.

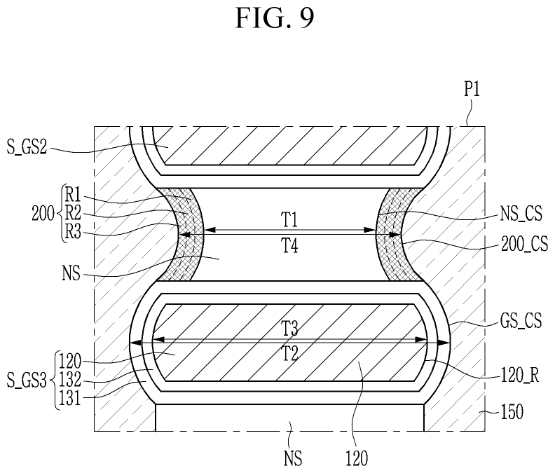

Hereinafter, a semiconductor device according to an embodiment will be described with reference to FIGS. 9 to 12.

FIG. 9 is an enlarged view corresponding to a region P1 of FIG. 2 of the semiconductor device according to the embodiment.

Since the embodiment illustrated in FIG. 9 has some parts the same or substantially the same as those of the embodiment illustrated in FIGS. 1 to 4, descriptions thereof will be omitted and differences will be mainly described. In this embodiment, some physical properties of the stacked pattern 200 are different from those of the foregoing embodiments, and will be described below.

Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise. The semiconductor device according to the embodiment may include a substrate 100, an active pattern AP, a plurality of gate structures GS, a source/drain pattern 150, a stacked pattern 200, a gate spacer 140, a capping layer 145, an etch stop layer 185, and an interlayer insulating layer 190.

In the foregoing embodiments, the stacked pattern 200 may include a first stacked pattern, a second stacked pattern, and a third stacked pattern sequentially stacked from the side surface NS_CS of the sheet pattern NS. At least one of the first stacked pattern, the second stacked pattern, and the third stacked pattern may include or be formed of different materials from the other. For example, the third stacked pattern may include or be formed of a material different from that of the first stacked pattern or the second stacked pattern, and/or the first stacked pattern may include or be formed of a material different from that of the second stacked pattern.

Referring to FIG. 9, in the present embodiment, the stacked pattern 200 may include a first region R1, a second region R2, and a third region R3. Here, the first region R1 may be a region corresponding to the first stacked pattern of the foregoing embodiments, the second region R2 may be a region corresponding to the second stacked pattern of the foregoing embodiments, and the third region R3 may be a region corresponding to the third stacked pattern of the foregoing embodiments.

The first region R1, the second region R2, and the third region R3 of the stacked pattern 200 may include or be formed of the same material. The first region R1, the second region R2, and the third region R3 of the stacked pattern 200 may include or be formed of, for example, silicon germanium (SiGe).

At least one of the first region R1, the second region R2, and the third region R3 of the stacked pattern 200 may have a different material composition ratio from the other. For example, when the stacked pattern 200 includes silicon germanium (SiGe), at least one of the composition ratio of silicon (Si) and germanium (Ge) included in the first region R1, the composition ratio of silicon (Si) and germanium (Ge) included in the second region R2, and the composition ratios of silicon (Si) and germanium (Ge) included in the second region R2 may be different from the other. For example, the germanium (Ge) concentration of the second region R2 is higher than the germanium (Ge) concentration of the first region R1, and the germanium (Ge) concentration of the third region R3 may be higher than the germanium (Ge) concentration of the second region R2. As another example, the concentration of germanium (Ge) in the first region R1 and the third region R3 is the same, and the germanium (Ge) concentration of the second region R2 may be higher or lower than the germanium (Ge) concentration of the first region R1. Such embodiments may be similarly applied (e.g., applied in the same way) even when the stacked pattern 200 includes silicon carbide (SIC) or other materials instead of silicon germanium (SiGe).

Alternatively, at least one of the first region R1, the second region R2, and the third region R3 of the stacked pattern 200 may have a different dopant concentration. For example, the dopant concentration of the first region R1, the dopant concentration of the second region R2, and the dopant concentration of the third region R3 may all be different from each other. Alternatively, the dopant concentration of the first region R1 and the dopant concentration of the second region R2 may be the same, and the dopant concentration of the third region R3 may be different from that of the first region R1, but the dopant concentrations are not limited thereto.

The dopant may be, for example, any one of boron (B), phosphorus (P), arsenic (As), antimonium (Sb), or a combination thereof. The dopant concentration may be, for example, 1×10¹⁷ cm⁻³ to 1×10²² cm⁻³. For example, when boron (B) is used as a dopant, the dopant concentration of the stacked pattern 200 may be 1×10¹⁷ cm⁻³ to 1×10²¹ cm⁻³. When phosphorus (P) is used as a dopant, the dopant concentration of the stacked pattern 200 may be 1×10¹⁷ cm⁻³ to 1×10²² cm⁻³. When arsenic (As) is used as a dopant, the dopant concentration of the stacked pattern 200 may be 1×10¹⁸ cm⁻³ to 1×10²¹ cm⁻³, but the dopant concentrations are not limited thereto.

Although the case where the material composition ratio of at least one of the first region R1, the second region R2, and the third region R3 of the stacked pattern 200 of the semiconductor device according to the embodiment is different, and/or the case where the dopant concentration in at least one of the first region R1, the second region R2, and the third region R3 of the stacked pattern 200 is different have been described, the materials are not limited thereto. For example, the stacked pattern 200 may include or be formed of materials and/or structures of a combination of the embodiments of FIGS. 1 to 4 and the embodiments of FIG. 9.

For example, the material of at least one of the first stacked pattern 210, the second stacked pattern 220, and the third stacked pattern 230 may be different, the material composition ratio of at least one of the first stacked pattern 210, the second stacked pattern 220, and the third stacked pattern 230 may be different, or the dopant concentration of at least one of the first stacked pattern 210, the second stacked pattern 220, and the third stacked pattern 230 may be different. For example, even when the first stacked pattern 210 and the second stacked pattern 220 include the same material and the first stacked pattern 210 and the third stacked pattern 230 include different materials, the first stacked pattern 210 and the second stacked pattern 220 may have different material composition ratios or different dopant concentrations. In this case, the first region R1 corresponds to the first stacked pattern 210, the second region R2 corresponds to the second stacked pattern 220, and the third region R3 corresponds to the third stacked pattern 230.

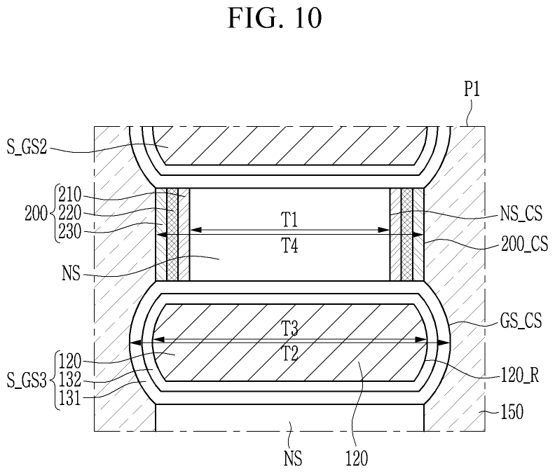

FIGS. 10 to 12 are enlarged views corresponding to the region P1 of FIG. 2 of the semiconductor device according to some embodiments.

Since the embodiments illustrated in FIGS. 10 to 12 have some parts the same or substantially the same as those of the embodiments illustrated in FIGS. 1 to 4, descriptions thereof will be omitted and differences will be mainly described. In the present embodiments, the shape of the sheet pattern NS and the shape of the stacked pattern 200 are different from those of the foregoing embodiments, and will be described below.

A plurality of sheet patterns NS may be positioned on an upper surface of the lower pattern BP. The plurality of sheet patterns NS may be spaced apart from the lower pattern BP in the third direction D3. Each sheet pattern NS may be spaced apart from the other sheet patterns NS in the third direction D3. The sheet pattern NS may include a side surface NS_CS facing in the first direction D1.

In the foregoing embodiments, the side surfaces NS_CS of the sheet patterns NS are curved surfaces. Each side surface NS_CS of the sheet patterns NS may have a concave shape, e.g., recessing toward the center of the sheet pattern NS.

In addition, the stacked patterns 200 extend along the side surfaces NS_CS of the sheet patterns NS. Each stacked pattern 200 covers a corresponding side surface NS_CS of the sheet patterns NS. The stacked pattern 200 may be conformally formed along the profile of the side surface of the sheet pattern NS. The side surface 200_CS of the stacked pattern 200 may have a concave shape, e.g., recessing toward the sheet pattern NS. For example, the side surface 200_CS of the stacked pattern 200 forming a boundary with the source/drain pattern 150 may have a concave shape.

Referring to FIG. 10, in the present embodiment, the side surface NS_CS of the sheet pattern NS may be flat. For example, the side surface NS_CS of the sheet pattern NS may be parallel to a vertical direction, e.g., in a cross-sectional view. However, even in this case, the first width T1 of the sheet pattern NS may be smaller than the third width T3 of the sub-gate electrode 120.

Also, in the present embodiment, the side surface 200_CS of the stacked pattern 200 may be flat (e.g., on a vertical plane). Since the stacked pattern 200 is conformally formed along the profile of the side surface of the sheet pattern NS, when the side surface NS_CS of the sheet pattern NS is flat (e.g., on a vertical plane), the side surface 200_CS of the stacked pattern 200 also has a planar shape. However, even in this case, the fourth width/distance T4 between the side surfaces 200_CS of the stacked pattern 200 positioned on both (e.g., opposite) sides of one sheet pattern NS may be smaller than the second width T2 of the sub-gate structures S_GS1, S_GS2, and S_GS3.

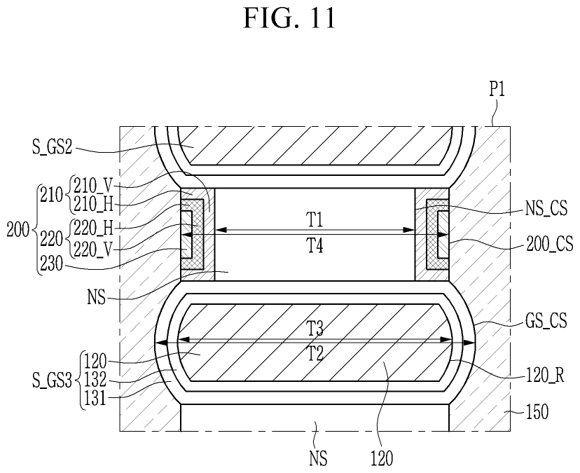

Referring to FIG. 11, in the present embodiment, the stacked pattern 200 may extend along the side surface NS_CS of the sheet pattern NS and the sub-gate structures S_GS1, S_GS2, and S_GS3. For example, the stacked pattern 200 may extend along the side surface of the sheet pattern NS, the upper surface of the third sub-gate structure S_GS3, and the lower surface of the second sub-gate structure S_GS2, e.g., in a cross-sectional view. The stacked pattern 200 may cover/contact the side surface NS_CS of the sheet pattern NS and portions of the sub-gate structures S_GS1, S_GS2, and S_GS3. The stacked pattern 200 may be formed to a constant thickness along the side surface NS_CS of the sheet pattern NS and the sub-gate structures S_GS1, S_GS2, and S_GS3.

The first stacked pattern 210 may include a first vertical portion 210_V and a first horizontal portion 210_H. The first vertical portion 210_V of the first stacked pattern 210 may extend in a vertical direction along the side surface NS_CS of the sheet pattern NS. The first horizontal portion 210_H of the first stacked pattern 210 may extend in a horizontal direction along the upper surface of the third sub-gate structure S_GS3 and/or the lower surface of the second sub-gate structure S_GS2. The first vertical portion 210_V and the first horizontal portion 210_H of the first stacked pattern 210 may have a uniform thickness. For example, the thickness is measured in a direction perpendicular to the extending direction.

The second stacked pattern 220 may include a second vertical portion 220_V and a second horizontal portion 220_H. The second vertical portion 220_V of the second stacked pattern 220 may extend in the vertical direction along a side surface of the first vertical portion 210_V of the first stacked pattern 210. The second horizontal portion 220_H of the second stacked pattern 220 may extend in the horizontal direction along a side surface of the first horizontal portion 210_H of the first stacked pattern 210. The second vertical portion 220_V and the first horizontal portion 210_H of the second stacked pattern 220 may be formed to have a uniform thickness. For example, the thickness is measured in a direction perpendicular to the extending direction.

The third stacked pattern 230 may be positioned within the second stacked pattern 220. The third stacked pattern 230 may fill a space between the second vertical portions 220_V of the second stacked pattern 220. For example, the third stacked pattern 230 may vertically overlap the second vertical portions 220_V of the second stacked pattern 220.

In FIG. 11, the first stacked pattern 210 and the second stacked pattern 220 each includes a horizontal portion and a vertical portion, but the first stacked pattern 210 and the second stacked pattern 220 are not limited thereto. For example, at least one of the first stacked pattern 210, the second stacked pattern 220, and the third stacked pattern 230 may include a horizontal portion and a vertical portion.

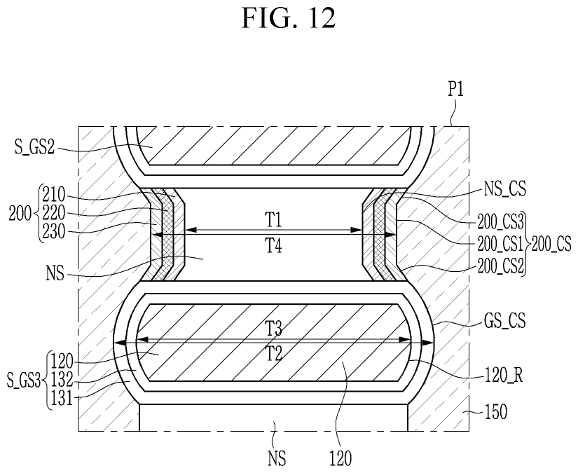

Referring to FIG. 12, in the present embodiment, the side surface NS_CS of the sheet pattern NS may include a flat surface (e.g., a surface on a vertical plane) and an inclined surface.

Also, in the present embodiment, the side surface 200_CS of the stacked pattern 200 may include a flat surface (e.g., a surface on a vertical plane) and an inclined surface. The side surface 200_CS of the stacked pattern 200 may include a first side surface 200_CS1, a first inclined surface 200_CS2, and a second inclined surface 200_CS3. Since the stacked pattern 200 is conformally disposed along the profile of the side surface of the sheet pattern NS, when the side surface NS_CS of the sheet pattern NS includes a flat surface (e.g., a surface on a vertical plane) and an inclined surface, the side surface 200_CS of the stacked pattern 200 may also include a vertical plane and an inclined surface. A vertical planar portion of the side surface NS_CS of the sheet pattern NS may be parallel to the third direction D3. For example, the side surface NS_CS of the sheet pattern NS may be a plane perpendicular to the upper surface of the substrate 100. A planar portion (e.g., a vertical planar portion) of the side surface 200_CS of the stacked pattern 200 may be parallel to the third direction D3. For example, the side surface 200_CS of the stacked pattern 200 may be a plane perpendicular to the upper surface of the substrate 100.

The side surface 200_CS of the stacked pattern 200 may have a concave shape recessing toward the sheet pattern NS. For example, the fourth width T4 between the first inclined surfaces 200_CS2 of the stacked pattern 200 positioned on both (e.g., opposite) sides of the sheet pattern NS may decrease in a direction receding from the lower surface of the second sub-gate structure S_GS2. The fourth width T4 between the second inclined surfaces 200_CS3 of the stacked pattern 200 positioned on both sides (e.g., opposite sides) of the sheet pattern NS may decrease in a direction receding from the upper surface of the third sub-gate structure S_GS3.

In FIG. 12, the stacked pattern 200 is illustrated as including the first side surface 200_CS1, the first inclined surface 200_CS2, and the second inclined surface 200_CS3, but is not limited thereto. For example, the side surface 200_CS of the stacked pattern 200 may include two or more inclined surfaces.

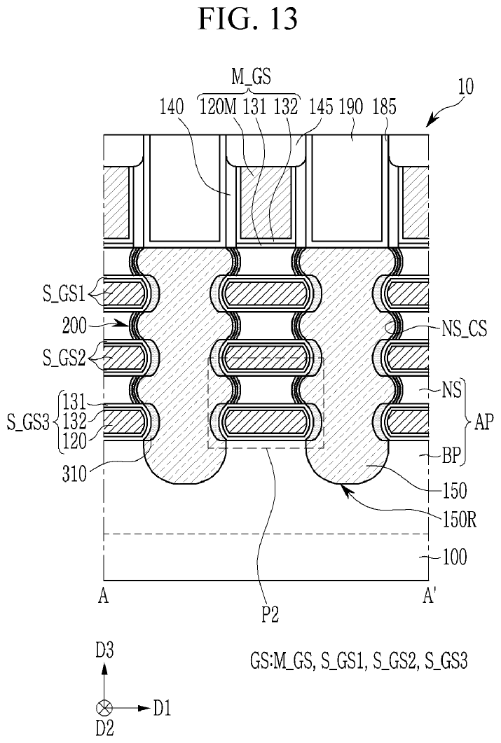

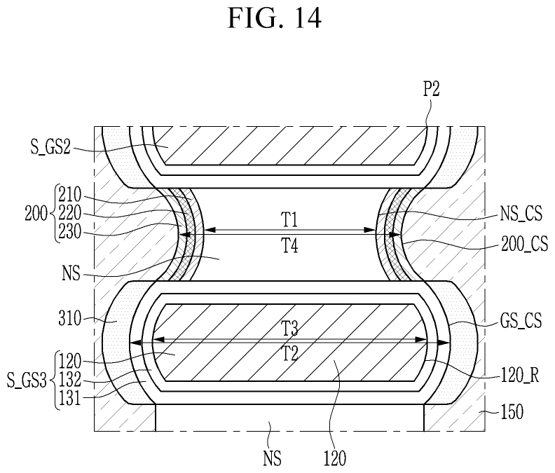

Hereinafter, a semiconductor device according to an embodiment will be described with reference to FIGS. 13 and 14.

FIG. 13 is a cross-sectional view taken along line A-A′ of FIG. 1 and illustrating a semiconductor device according to an embodiment. FIG. 14 is an enlarged view of a region P2 of FIG. 13.

Since the embodiments illustrated in FIGS. 13 and 14 have some parts the same or substantially the same as those of the embodiment illustrated in FIGS. 1 to 4, descriptions thereof will be omitted and differences will be mainly described. The semiconductor device according to the present embodiment is different from the foregoing embodiments in that the semiconductor device further includes an inner spacer, which will be described below.

A semiconductor device according to an embodiment may include a substrate 100, an active pattern AP, a plurality of gate structures GS, a source/drain pattern 150, a stacked pattern 200, a gate spacer 140, a capping layer 145, an etch stop layer 185, an interlayer insulating layer 190, and an inner spacer 310.

In the foregoing embodiments, the sub-gate structures S_GS1, S_GS2, and S_GS3 contact the source/drain pattern 150. The source/drain pattern 150 may be positioned on side surfaces of the sub-gate structures S_GS1, S_GS2, and S_GS3. For example, the source/drain patterns 150 may contact side surfaces of the interfacial insulating layers 131 of the sub-gate structures S_GS1, S_GS2, and S_GS3.

Referring to FIGS. 13 and 14, in the present embodiment, inner spacers 310 may be positioned between the sub-gate structures S_GS1, S_GS2, and S_GS3 and the source/drain pattern 150. The inner spacers 310 may contact the sub-gate structures S_GS1, S_GS2, and S_GS3 and the source/drain pattern 150. The inner spacers 310 may be positioned between the lower pattern BP and the sheet pattern NS, and between the sheet patterns NS adjacent to each other in the third direction D3.

The inner spacers 310 may protrude toward the source/drain pattern 150 more than the sub-gate structures S_GS1, S_GS2, and S_GS3. A side surface of the inner spacer 310 may have a convex shape having a central portion protruding toward the source/drain pattern 150. For example, a side surface of the inner spacer 310 facing/contacting the source/drain pattern 150 may have a convex shape.

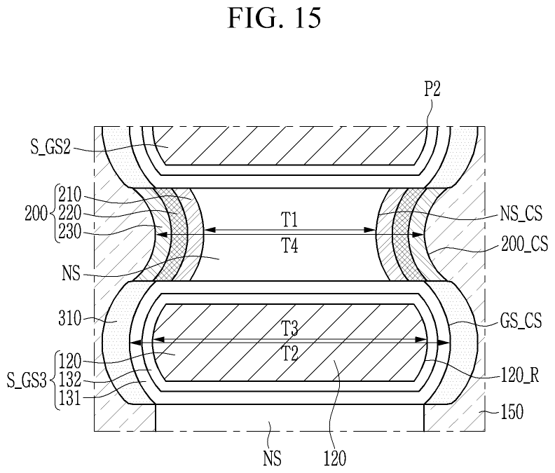

Hereinafter, a semiconductor device according to an embodiment will be described with reference to FIG. 15.

FIG. 15 is an enlarged view corresponding to the region P2 of FIG. 13 illustrating the semiconductor device according to the embodiment.

Since the embodiment illustrated in FIG. 15 has some parts the same or substantially the same as those of the embodiment illustrated in FIGS. 13 and 14, descriptions thereof will be omitted and differences will be mainly described. The semiconductor device according to the present embodiment is different from the foregoing embodiments in the stacked pattern and the arrangement of the inner spacers, which will be described below.

A semiconductor device according to an embodiment may include a substrate 100, an active pattern AP, a plurality of gate structures GS, a source/drain pattern 150, a stacked pattern 200, a gate spacer 140, a capping layer 145, an etch stop layer 185, an interlayer insulating layer 190, and an inner spacer 310.

In the foregoing embodiment, the inner spacer 310 may protrude toward the source/drain pattern 150 more than the sub-gate structures S_GS1, S_GS2, and S_GS3. A side surface of the inner spacer 310 may have a convex shape having a central portion protruding toward the source/drain pattern 150. The inner spacer 310 does not overlap the stacked pattern 200, e.g., in a vertical direction.

Referring to FIG. 15, in the present embodiment, the stacked pattern 200 may be positioned between the inner spacers 310 adjacent in the third direction D3. Also, the stacked pattern 200 may be positioned between the source/drain pattern 150 and the sheet pattern NS. The stacked pattern 200 may extend along the side surface NS_CS of the sheet pattern NS.

A portion of the stacked pattern 200 may overlap the inner spacer 310 in the third direction D3. For example, one surface (e.g., a bottom surface or a top surface) of the third stacked pattern 230 may be in contact with the inner spacer 310. The sub-gate structures S_GS1, S_GS2, and S_GS3 may be spaced apart from the source/drain pattern 150 by the inner spacers 310.

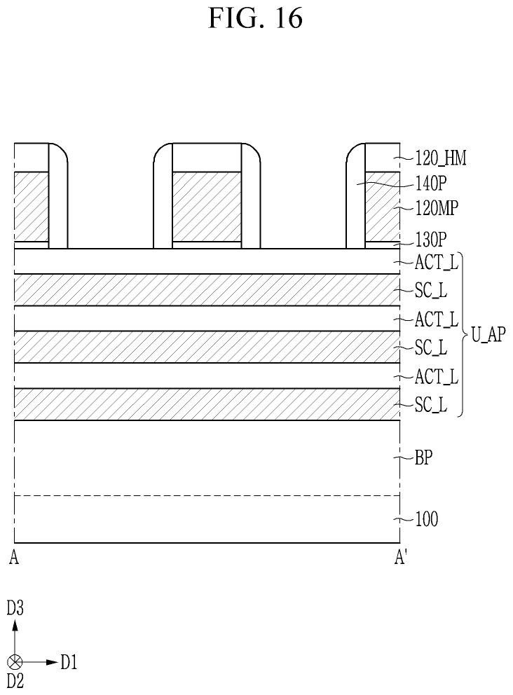

Hereinafter, a method of manufacturing a semiconductor device according to an embodiment will be described with reference to FIGS. 16 to 22.

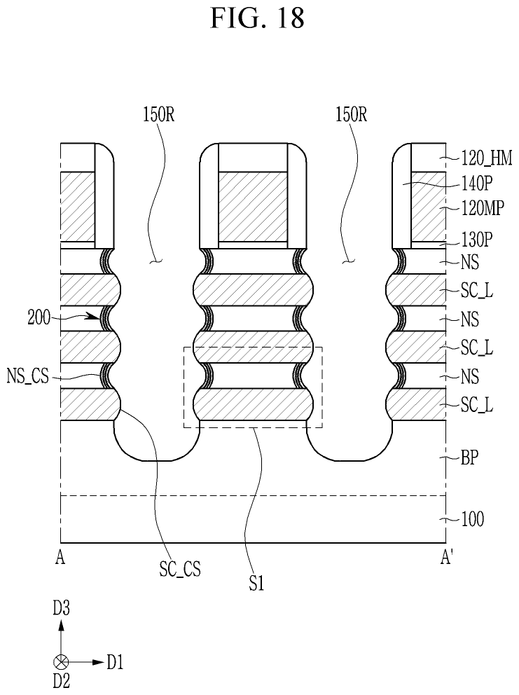

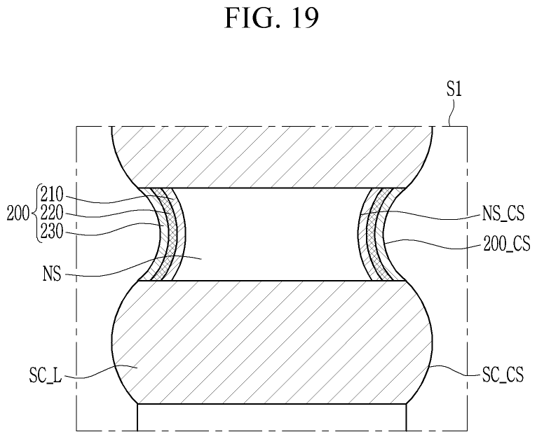

FIGS. 16 to 18 and 20 to 22 are cross-sectional views illustrating intermediate steps of a method of manufacturing a semiconductor device according to an embodiment. FIG. 19 is an enlarged view of the region S1 of FIG. 18.

As illustrated in FIG. 16, a lower pattern BP and an upper pattern structure U_AP are formed on the substrate 100.

The upper pattern structure U_AP may be positioned on the lower pattern BP. The upper pattern structure U_AP may include sacrificial patterns SC_L and active patterns ACT_L alternately stacked on the lower pattern BP. For example, the sacrificial patterns SC_L may include or be formed of silicon germanium (SiGe). The active pattern ACT_L may include or be formed of silicon (Si).

Subsequently, a preliminary gate insulating layer 130P, a preliminary main gate electrode 120MP, and a preliminary capping layer 120_HM are formed on the upper pattern structure U_AP. The preliminary gate insulating layer 130P may include or be formed of, for example, silicon oxide, but is not limited thereto. The preliminary main gate electrode 120MP may include or be formed of, for example, polysilicon, but is not limited thereto. The preliminary capping layer 120_HM may include or be formed of, for example, silicon nitride, but is not limited thereto.

A preliminary gate spacer 140p may be formed on both side surfaces of the preliminary main gate electrode 120MP.

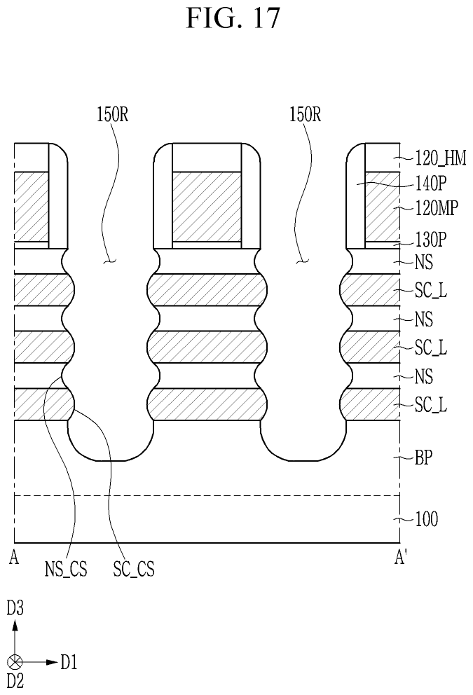

As illustrated in FIG. 17, a source/drain recess 150R is formed by etching at least a portion of the upper pattern structure U_AP by using the preliminary main gate electrode 120MP, the preliminary capping layer 120_HM and/or the preliminary gate spacer 140p as a mask

A portion of the source/drain recess 150R may be formed in the lower pattern BP.

As the source/drain recess 150R is formed, the active pattern ACT_L is separated to form the sheet patterns NS. The sheet patterns NS may be positioned on both sides of the source/drain recess 150R. The intermediate structure of the method of manufacturing the semiconductor device may have a structure in which the sheet patterns NS and the sacrificial patterns SC_L are alternately stacked. At this time, the length (e.g., in the first direction) of each sheet pattern NS may be different from or the same as other sheet patterns NS.

In this case, in the process of etching at least a portion of the upper pattern structure U_AP to form the source/drain recess 150R, the etching process may be performed by using an etchant having a relatively high etching rate for the active pattern ACT_L. For example, when the sacrificial patterns SC_L include or are formed of silicon germanium (SiGe) and the sheet patterns NS (the active pattern ACT_L) include or are formed of silicon (Si), the etching process may be performed by using an etchant having a relatively high etching rate for silicon. Therefore, the sheet pattern NS (active pattern ACT_L) exposed by the source/drain recess 150R is etched more than the sacrificial patterns SC_L exposed by the source/drain recess 150R, and each sacrificial pattern SC_L may have a shape protruding toward the source/drain recess 150R from side surfaces of the sheet patterns NS. In certain embodiments, the width of the sacrificial pattern SC_L in the first direction D1 may be smaller than the width of the sheet patterns NS in the first direction D1.

As a portion of a sheet pattern NS exposed by the source/drain recess 150R is removed, the side surface NS_CS of the sheet pattern NS may have a concave shape recessing toward the inside of the sheet pattern. For example, the side surface NS_CS of the sheet pattern NS facing the source/drain recess 150R may have a concave shape. Also, in the process of removing the portion of the sheet pattern NS, the portion of the side surface SC_CS of the sacrificial pattern SC_L exposed by the source/drain recess 150R may be removed together. Accordingly, the side surface of the sacrificial pattern SC_L may be etched into a rounded shape. For example, the side surface SC_CS of the sacrificial pattern SC_L may have a convex shape, e.g., having a central portion protruding toward the source/drain recess 150R. For example, the side surface SC_CS of the sacrificial pattern SC_L facing the source/drain recess 150R may have a convex shape.

Through this, the shape of the source/drain recess 150R may be formed unevenly. For example, side surfaces of the source/drain recess 150R may be uneven. However, the method is not limited thereto. For example, after at least a portion of the upper pattern structure U_AP is etched to form the source/drain recess 150R, a process of selectively etching the sheet pattern NS exposed by the source/drain recess 150R may be additionally performed in certain embodiments.

As illustrated in FIGS. 18 and 19, the stacked pattern 200 is formed on the side surface NS_CS of the sheet pattern NS.

First, the first stacked pattern 210 is formed on the side surface NS_CS of the sheet pattern NS and between the sacrificial patterns SC_L adjacent in the third direction D3. First stacked patterns 210 may be formed on both sides of the sheet pattern NS. The first stacked pattern 210 may extend along the side surface NS_CS of the sheet pattern NS. The first stacked pattern 210 may be conformally formed along the profile of a side surface of the sheet pattern NS.

Subsequently, the second stacked pattern 220 and the third stacked pattern 230 are sequentially formed on the side surfaces of the first stacked pattern 210 and between the sacrificial patterns SC_L adjacent in the third direction D3. The second stacked pattern 220 may extend along the side surface of the first stacked pattern 210. The second stacked pattern 220 may be conformally formed along the profile of a side surface of the first stacked pattern 210. The third stacked pattern 230 may extend along the side surface of the second stacked pattern 220. The third stacked pattern 230 may be conformally formed along the profile of a side surface of the second stacked pattern 220.

The stacked pattern 200 may have a concave shape, e.g., at a side surface facing the source/drain recess 150R, e.g., recessing toward the sheet pattern NS and the side surface facing the source/drain recess 150R may be positioned farther from a center of the source/drain recess 150R than a side surface of the sacrificial pattern SC_L facing the source/drain recess 150R. The side surface 200_CS of the stacked pattern 200 may have a concave shape, e.g., at a side surface facing the source/drain recess 150R, e.g., recessing toward the sheet pattern NS. For example, the side surface 200_CS of the stacked pattern 200 facing the source/drain recess 150R may have a concave shape, but is not limited thereto.

At least one of the first stacked pattern 210, the second stacked pattern 220, and the third stacked pattern 230 may include or be formed of a different material from the other. For example, the third stacked pattern 230 may include or be formed of a material different from that of the first stacked pattern 210 or the second stacked pattern 220, or the first stacked pattern 210 may include or be formed of a material different from that of the second stacked pattern 220.

For example, when the third stacked pattern 230 includes or is formed of a first material, the first stacked pattern 210 or the second stacked pattern 220 may include or be formed of a second material different from the first material. Alternatively, when either the first stacked pattern 210 or the second stacked pattern 220 includes or is formed of the second material, the other one of the first stacked pattern 210 and the second stacked pattern 220 includes or is formed of a third material different from the two materials. However, the materials are not limited thereto, and when the third stacked pattern 230 includes or is formed of a material different from that of the first stacked pattern 210 or the second stacked pattern 220, the first stacked pattern 210 and the second stacked pattern 220 may include or be formed of the same material as each other. Here, the first material may be, for example, silicon (Si), silicon germanium (SiGe), or a combination thereof. The second material may be, for example, silicon (Si), silicon germanium (SiGe), silicon carbide (SIC), or a combination thereof. The third material may be, for example, silicon (Si), silicon germanium (SiGe), or a combination thereof.

The stacked pattern 200 may be formed by using an atomic layer deposition (ALD) process, a chemical vapor deposition (CVD) process, or the like. However, the process is not limited thereto, and the stacked pattern 200 may be formed in various other ways.

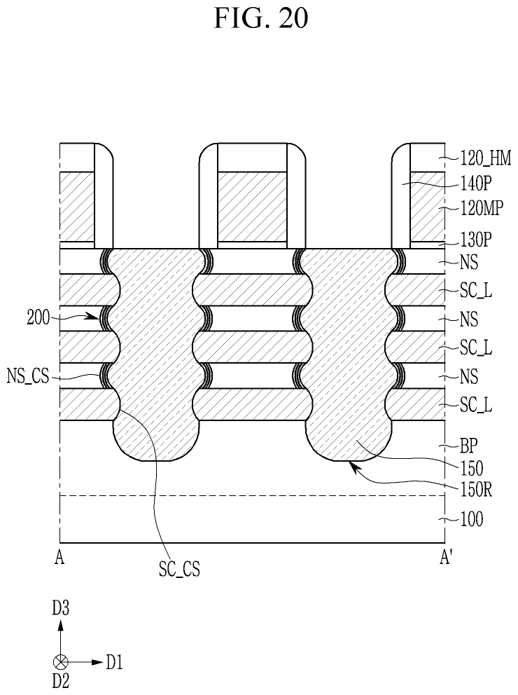

As illustrated in FIG. 20, a source/drain pattern 150 is formed in the source/drain recess 150R.

The source/drain pattern 150 may be formed on the lower pattern BP. The source/drain pattern 150 may be formed using an epitaxial growth method. A first liner layer 151 may be formed along a sidewall and a bottom surface of the source/drain recess 150R. The source/drain pattern 150 may contact the sacrificial pattern SC_L and the stacked pattern 200. The source/drain pattern 150 may include or be formed of silicon germanium (SiGe).

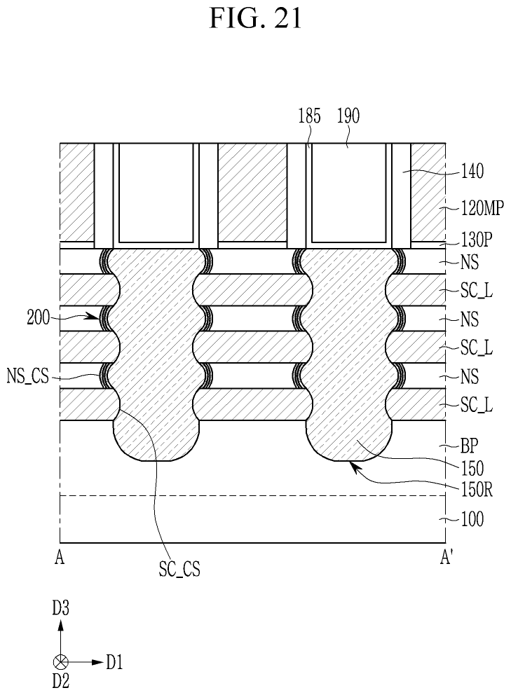

As illustrated in FIG. 21, an etch stop layer 185 and an interlayer insulating layer 190 are sequentially formed on the source/drain pattern 150.

Subsequently, a portion of the interlayer insulating layer 190, a portion of the etch stop layer 185, and the preliminary capping layer 120_HM are removed to expose an upper surface of the preliminary main gate electrode 120MP. The gate spacer 140 may be formed while the upper surface of the preliminary main gate electrode 120MP is exposed.

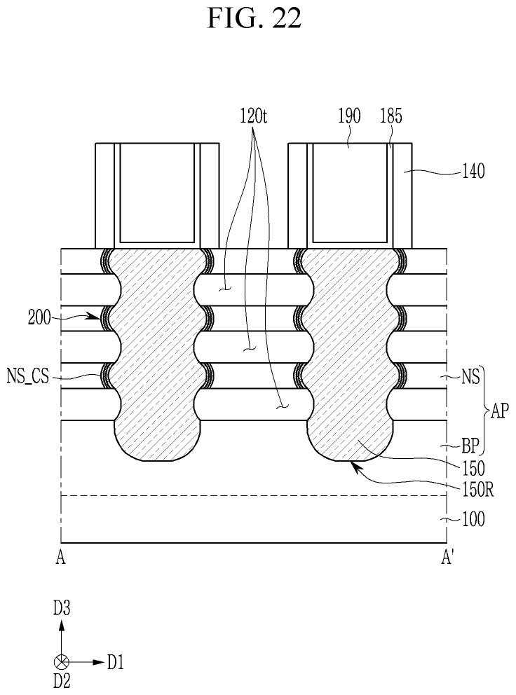

As illustrated in FIG. 22, the upper pattern structure U_AP between the gate spacers 140 is exposed by removing the preliminary gate insulating layer 130P and the preliminary main gate electrode 120MP.

Next, a gate trench 120t is formed between the sheet patterns NS.

Next, as illustrated in FIG. 2, an interfacial insulating layer 131, a gate insulating layer 132, and a sub-gate electrode 120 may be sequentially formed in the gate trench 120t. In addition, the semiconductor device of FIG. 2 may be formed by sequentially forming the main gate electrode 120M and the capping layer 145.

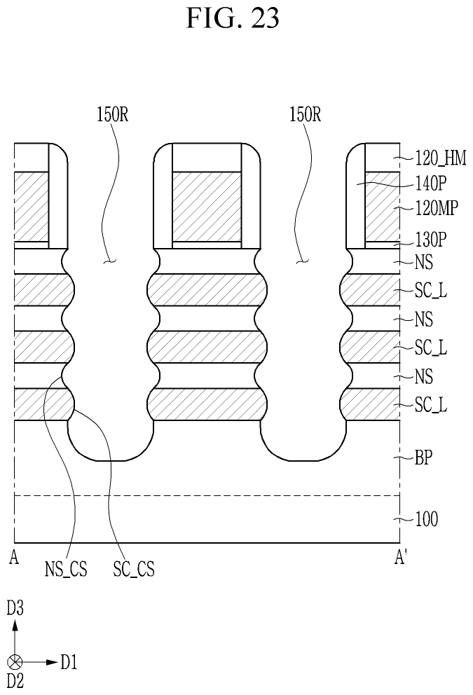

Hereinafter, a semiconductor device according to an embodiment will be described with reference to FIGS. 23 to 26.

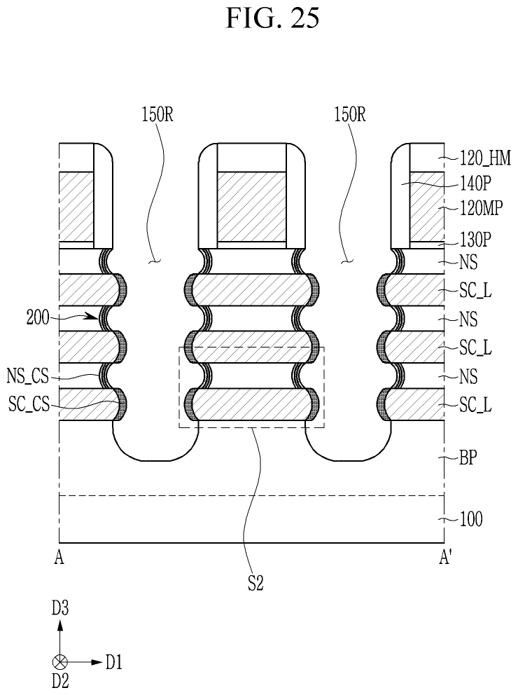

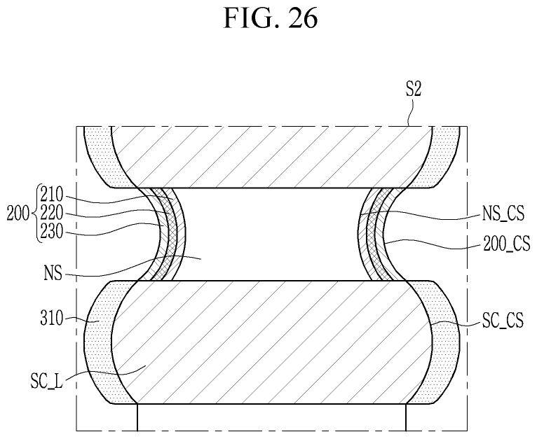

FIGS. 23 to 25 are cross-sectional views illustrating a method of manufacturing a semiconductor device according to an embodiment. FIG. 26 is an enlarged view of a region S2 of FIG. 25.

As illustrated in FIG. 23, a lower pattern BP and an upper pattern structure U_AP are formed on the substrate 100.

Subsequently, a preliminary gate insulating layer 130P, a preliminary main gate electrode 120MP, and a preliminary capping layer 120_HM are formed on the upper pattern structure U_AP. A preliminary gate spacer 140p may be formed on both side surfaces of the preliminary main gate electrode 120MP.

A source/drain recess 150R is formed by etching at least a portion of the upper pattern structure U_AP by using the preliminary main gate electrode 120MP, the preliminary capping layer 120_HM and/or the preliminary gate spacer 140p as a mask. After at least a portion of the upper pattern structure U_AP is etched to form the source/drain recess 150R, a process of selectively etching the active pattern ACT_L exposed by the source/drain recess 150R may be additionally performed. Accordingly, a side surface ACT_CS of the active pattern ACT_L may have a concave shape toward the inside. For example, the side surface ACT_CS of the active pattern ACT_L facing the source/drain recess 150R may have a concave shape. A side surface SC_CS of the sacrificial pattern SC_L may have a convex shape, e.g., having a central portion protruding toward the source/drain recess 150R. For example, the side surface SC_CS of the sacrificial pattern SC_L facing the source/drain recess 150R may have a convex shape. The sacrificial patterns SC_L are the same or substantially the same as those of the embodiments of FIGS. 16 to 22, so that descriptions thereof are omitted.

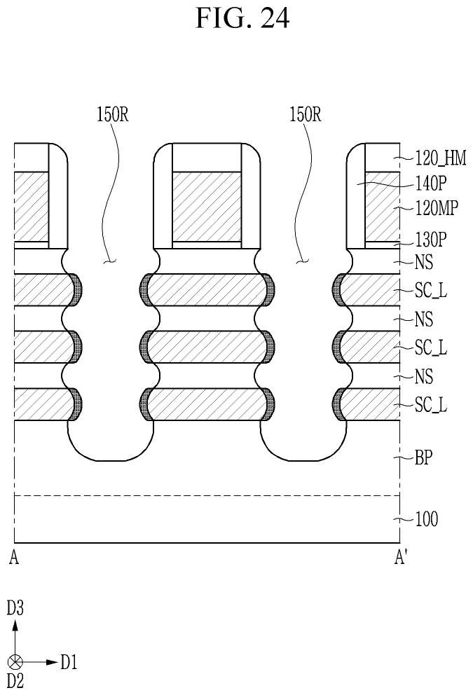

As illustrated in FIG. 24, an inner spacer 310 is formed on the side surface of the sacrificial pattern SC_L. The inner spacer 310 may be positioned to cover/contact both (e.g., opposite) side surfaces of the sacrificial pattern SC_L. The inner spacer 310 may protrude toward the source/drain recess 150R more than the sacrificial pattern SC_L. A side surface of the inner spacer 310 may have a convex shape, e.g., having a central portion protruding toward the source/drain recess 150R. For example, the side surface of the inner spacer 310 having the convex shape faces the source/drain recess 150R.

As illustrated in FIGS. 25 and 26, the stacked pattern 200 is formed on the side surface ACT_CS of the active pattern ACT_L.

First, the first stacked pattern 210 is formed on the side surface ACT_CS of the active pattern ACT_L and between the sacrificial patterns SC_L adjacent in the third direction D3. The first stacked patterns 210 may be formed on both (e.g., opposite) sides of the active pattern ACT_L. The first stacked pattern 210 may extend along the side surface ACT_CS of the active pattern ACT_L. The first stacked pattern 210 may be conformally formed along the profile of the side surface of the active pattern ACT_L.

Subsequently, the second stacked pattern 220 and the third stacked pattern 230 are sequentially formed on the side surfaces of the first stacked pattern 210 and between the sacrificial patterns SC_L adjacent to each other in the third direction D3. The second stacked pattern 220 may extend along the side surface of the first stacked pattern 210. The second stacked pattern 220 may be conformally formed along the profile of the side surface of the first stacked pattern 210. The third stacked pattern 230 may extend along the side surface of the second stacked pattern 220. The third stacked pattern 230 may be conformally formed along the profile of the side surface of the second stacked pattern 220. The stacked patterns are the same or substantially the same as those of the embodiments of FIGS. 16 to 22, and descriptions thereof are omitted.

Subsequently, the processes of FIGS. 20 to 22 are performed, and as illustrated in FIG. 13, the interfacial insulating layer 131, the gate insulating layer 132, and the sub-gate electrode 120 may be sequentially formed. In addition, the semiconductor device of FIG. 13 may be formed by sequentially forming the main gate electrode 120M and the capping layer 145.

Although embodiments have been described in detail above, the scope of the present invention is not limited by the embodiments. Various changes and modifications using the basic concept of the present invention defined in the accompanying claims by those skilled in the art shall be construed to belong to the scope of the present invention.

For example, even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context indicates otherwise.

### DESCRIPTION OF SYMBOLS

100: Substrate
105: Field insulating layer
AP: Active pattern
NS: Sheet pattern
150: Source/drain pattern
GS: Gate structure
120: Gate electrode
200: Stacked pattern
210: First stacked pattern
220: Second stacked pattern
230: Third stacked pattern

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor device comprising:
an active pattern including a lower pattern and a plurality of sheet patterns spaced apart from each other on the lower pattern;
a gate structure positioned on the lower pattern and surrounding the sheet patterns;
source/drain patterns positioned on both sides of the gate structure, and
stacked patterns positioned between the source/drain patterns and the sheet patterns,
wherein a stacked pattern includes
a first stacked pattern and a second stacked pattern sequentially stacked on a side surface of a sheet pattern, the second stacked pattern including a material different from a material of the first stacked pattern, and
a first width of the sheet pattern is smaller than a second width of the gate structure.

2. The semiconductor device of claim 1, wherein the gate structure includes:
a main gate structure positioned on the sheet patterns, and
a plurality of sub-gate structures positioned between the sheet patterns and between the sheet pattern and the lower pattern,
wherein each of the plurality of sub-gate structures includes:
a sub-gate electrode; and
a gate insulating layer positioned between the sub-gate electrode and the sheet pattern and between the sub-gate electrode and the source/drain patterns, and
wherein a third width of the sub-gate electrode is greater than the first width.

3. The semiconductor device of claim 2, wherein the sub-gate structure protrudes toward a source/drain pattern more than the sheet pattern.

4. The semiconductor device of claim 3, wherein a side surface of the sub-gate structure facing a source/drain pattern has a convex shape.

5. The semiconductor device of claim 2, wherein a side surface of the stacked pattern facing a source/drain pattern has a concave shape.

6. The semiconductor device of claim 2, wherein the stacked pattern is positioned between adjacent sub-gate structures.

7. The semiconductor device of claim 2, wherein a minimum width of the sheet pattern is smaller than a maximum width of the sub-gate structure.

8. The semiconductor device of claim 2, further comprising:
an inner spacer positioned between the sub-gate structure and a source/drain pattern,
wherein the stacked pattern is positioned between the inner spacers.

9. The semiconductor device of claim 1, wherein concentrations of dopants in the first stacked pattern and the second stacked pattern are different.

10. The semiconductor device of claim 9, wherein the dopants are arsenic, boron, phosphorus, antimonium, or a combination thereof.

11. The semiconductor device of claim 9, wherein the concentrations of the dopants in the first stacked pattern and the second stacked pattern are 1×10¹⁷ cm⁻³ to 1×10²² cm⁻³.

12. The semiconductor device of claim 1, wherein one of the first stacked pattern and the second stacked pattern includes silicon, and the other of the first stacked pattern and the second stacked pattern includes silicon germanium.

13. The semiconductor device of claim 1, wherein the stacked pattern further includes a third stacked pattern positioned between the second stacked pattern and a source/drain pattern, and
the third stacked pattern and the second stacked pattern include different materials from each other.

14. The semiconductor device of claim 13, wherein the third stacked pattern includes silicon or silicon germanium, and the second stacked pattern includes silicon carbide.

15. A semiconductor device comprising:
an active pattern including a lower pattern and a plurality of sheet patterns spaced apart from each other on the lower pattern;
sub-gate structures positioned on the lower pattern and surrounding the sheet patterns;
source/drain patterns positioned on both sides of a sub-gate structure; and
a stacked pattern positioned between a source/drain pattern and a sheet pattern, and including a first stacked pattern and a second stacked pattern sequentially stacked from a side surface of the sheet pattern,
wherein at least one of materials of the first stacked pattern and the second stacked pattern, composition ratios of materials of the first stacked pattern and the second stacked pattern, and concentrations of dopants in the first stacked pattern and the second stacked pattern is different from each other between the first stacked pattern and the second stacked pattern.

16. The semiconductor device of claim 15, wherein the stacked pattern further includes a third stacked pattern positioned between the second stacked pattern and the source/drain pattern, and
the third stacked pattern and the second stacked pattern include different materials from each other.

17. The semiconductor device of claim 16, wherein the third stacked pattern includes silicon or silicon germanium, and the second stacked pattern includes silicon carbide.

18. The semiconductor device of claim 16, wherein the dopants are arsenic, boron, phosphorus, antimonium, or a combination thereof.

19. A semiconductor device comprising:
an active pattern including a lower pattern and a plurality of sheet patterns spaced apart from each other on the lower pattern;
sub-gate structures positioned on the lower pattern and surrounding the sheet patterns;
source/drain patterns positioned on both sides of a sub-gate structure, and
stacked patterns positioned between the source/drain patterns and the sheet patterns,
wherein the stacked patterns include
a first stacked pattern and a second stacked pattern sequentially stacked on a side surface of a sheet pattern, the second stacked pattern including a material different from a material of the first stacked pattern, and
the sub-gate structure protrudes toward a source/drain pattern more than the sheet pattern, and a side surface of the sub-gate structure is convex.

20. The semiconductor device of claim 19, wherein the sub-gate structure protrudes toward the source/drain pattern more than the stacked patterns.
